(19) United States
(12) Patent Application Publication
(10) Pub. No.: US 2026/0074825 A1
(43) Pub. Date: Mar. 12, 2026

(54) GRAY MAPPING FOR VARIABLE-TO-FIXED DISTRIBUTION MATCHING

(71) Applicant: QUALCOMM Incorporated, San Diego, CA (US)

(72) Inventors: Wei LIU, Beijing (CN); Thomas Joseph RICHARDSON, South Orange, NJ (US); Liangming WU, Beijing (CN); Changlong XU, Beijing (CN); Ori SHENTAL, Marlboro, NJ (US); Hao XU, Beijing (CN)

(21) Appl. No.: 18/872,721

(22) PCT Filed: Jul. 20, 2022
(86) PCT No.: PCT/CN2022/106697

§ 371 Date: Dec. 6, 2024

(51) Int. Cl. H04L 1/00; H03M 13/25; H04L 27/34; H04W 28/04

(52) U.S. Cl. CPC H04L 1/0042; H03M 13/25; H04W 28/04; H04L 27/34

(57) ABSTRACT

Certain aspects of the present disclosure provide a method for wireless communications by a transmitter. The method generally includes obtaining a first block of information bits from a buffer, generating a first sequence of probabilistic amplitude shaped (PAS) symbols, from the first block of information bits, using a demapper function and an arithmetic decoder function, transmitting the first sequence of PAS symbols to a receiver, combining a first subset of the first block of information bits, identified by an arithmetic encoder function and a mapper function, with a second block of information bits from the buffer, generating a second sequence of PAS symbols, from the combined first subset of the first block of information bits and second block of information bits, using the demapper function and the arithmetic decoder function, and transmitting the second sequence of PAS symbols to the receiver.

### BACKGROUND

### Field of the Disclosure

Aspects of the present disclosure relate to wireless communications, and more particularly, to techniques for wireless transmission.

### Description of Related Art

Wireless communication systems are widely deployed to provide various telecommunication services such as telephony, video, data, messaging, broadcasts, or other similar types of services. These wireless communication systems may employ multiple-access technologies capable of supporting communication with multiple users by sharing available wireless communication system resources with those users.

Although wireless communication systems have made great technological advancements over many years, challenges still exist. For example, complex and dynamic environments can still attenuate or block signals between wireless transmitters and wireless receivers. Accordingly, there is a continuous desire to improve the technical performance of wireless communications systems, including, for example: improving speed and data carrying capacity of communications, improving efficiency of the use of shared communications mediums, reducing power used by transmitters and receivers while performing communications, improving reliability of wireless communications, avoiding redundant transmissions and/or receptions and related processing, improving the coverage area of wireless communications, increasing the number and types of devices that can access wireless communication systems, increasing the ability for different types of devices to intercommunicate, increasing the number and type of wireless communication mediums available for use, and the like. Consequently, there exists a need for further improvements in wireless communications systems to overcome the aforementioned technical challenges and others.

### SUMMARY

One aspect provides a method of wireless communication at a transmitter. The method generally includes obtaining a first block of information bits from a buffer, generating a first sequence of probabilistic amplitude shaped (PAS) symbols, from a first block of information bits, using a demapper function and an arithmetic decoder function, transmitting the first sequence of PAS symbols to a receiver, combining a first subset of the first block of information bits, identified by an arithmetic encoder function and a mapper function, with a second block of information bits from the buffer, generating a second sequence of PAS symbols, from the combined first subset of the first block of information bits and second block of information bits, using the demapper function and the arithmetic decoder function, and transmitting the second sequence of PAS symbols to the receiver.

One aspect provides a method of wireless communication at a receiver. The method generally includes receiving, from a transmitter, a first sequence of probabilistic amplitude shaped (PAS) symbols generated based on a first block of information bits, identifying a first subset of the first block of information bits, using an arithmetic encoder function and a mapper function, storing, in a buffer, a second subset of the first block of information bits, using an arithmetic encoder function and a mapper function, wherein the second subset comprises a remaining set of the first block of information bits after discarding the first subset, receiving a second sequence of PAS symbols, generated by combining the first subset of the first block of information bits with a second block of information bits, and updating the buffer based on a subset of combined first subset and second block of information bits, identified using the arithmetic encoder function and the mapper function.

Other aspects provide: an apparatus operable, configured, or otherwise adapted to perform the aforementioned methods as well as those described elsewhere herein; a non-transitory, computer-readable media comprising instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and an apparatus comprising means for performing the aforementioned methods as well as those described elsewhere herein. By way of example, an apparatus may comprise a processing system, a device with a processing system, or processing systems cooperating over one or more networks.

The following description and the appended figures set forth certain features for purposes of illustration.

### BRIEF DESCRIPTION OF DRAWINGS

The appended figures depict certain features of the various aspects described herein and are not to be considered limiting of the scope of this disclosure.

FIG. 1 depicts an example wireless communication network.

FIG. 2 depicts an example disaggregated base station architecture.

FIG. 3 depicts aspects of an example base station and an example user equipment.

FIGS. 4A, 4B, 4C, and 4D depict various example aspects of data structures for a wireless communication network.

FIG. 5 depicts an example implementation of a transmitter and receiver.

FIG. 6A and FIG. 6B depict examples of an amplitude shaper and amplitude deshaper, respectively.

FIG. 7A and FIG. 7B depict examples of another amplitude shaper and another amplitude deshaper, respectively.

FIG. 8 depicts example output of an amplitude deshaper.

FIG. 9A and FIG. 9B depict examples of an amplitude shaper and an amplitude deshaper, in accordance with aspects of the present disclosure.

FIG. 10 depicts example output of an amplitude deshaper, in accordance with aspects of the present disclosure.

FIG. 11 depicts example of a coding scheme for variable to fixed distribution matching, in accordance with aspects of the present disclosure.

FIG. 12 depicts an example implementation of a transmitter and receiver with a coding scheme for variable to fixed distribution matching, in accordance with aspects of the present disclosure.

FIG. 13A, FIG. 13B, FIG. 13C, and FIG. 13D depict an example of iterative transmission processing with a transmitter and receiver with a coding scheme for variable to fixed distribution matching, in accordance with aspects of the present disclosure.

FIG. 14 depicts a method for wireless communications.

FIG. 15 depicts a method for wireless communications.

FIG. 16 depicts aspects of an example communications device.

FIG. 17 depicts aspects of an example communications device.

### DETAILED DESCRIPTION

Aspects of the present disclosure provide apparatuses, methods, processing systems, and computer-readable mediums for wireless transmission. In particular, techniques presented herein incorporate encoding techniques (such as Gray mapping) for transmission schemes that involve variable-to-fixed distribution matching.

Communication over a channel is possible if the transmission rate over the channel satisfies a capacity based on the transmission power and the signal-to-noise ratio (SNR). The Shannon Capacity refers to a theorem that defines a maximum amount of information that can be transmitted over a channel (e.g. a wireless channel). Traditionally used coded modulation (CM) techniques, such as amplitude shift keying (ASK) and quadrature amplitude modulation (QAM), have signal constellations that are characterized by equidistant signal points and uniform signaling (e.g., a non-Gaussian distribution of information), meaning each signal point is transmitted with a same probability. Unfortunately, uniform signaling may optimistically achieve an achievable information rate (AIR) that is 1.53 dB (0.255 bits per dimension (bit/1-D)) away from the capacity of the AWGN channel (sometimes referred to as the “shaping gap”).

To close the shaping gap and to increase spectral efficiency, signal shaping techniques may be applied to generate a non-uniform distribution of the information. For example, in geometric shaping, constellation points are arranged in the complex plane in a non-equidistant manner to mimic a capacity achieving distribution. Probabilistic shaping, on the other hand, starts with a constellation with equidistant signal points (e.g., ASK or QAM) but assigns different probabilities to different constellation points.

Examples of probabilistic shaping including trellis shaping and shell mapping. Probabilistic amplitude shaping (PAS) is another technique for employing probabilistic shaping that has achieved high throughput for commercial use in optical core networks (e.g., over 10 GB/second). Probabilistic shaping offers low-complexity and flexible integration with existing coding schemes. PAS generally provides low-complexity integration of amplitude shaping into existing binary forward error correction (FEC) systems and large shaping gain and inherent rate adaptation functionality.

In some cases, PAS based transmitters may perform additional processing to increase spectral efficiency. For example, in a variable-to-fixed distribution matching scheme, a PAS based transmitter may perform processing to identify a number of information bits that can likely be received successfully at the receiver (by emulating receiver-side processing at the transmitter), in order to avoid transmitting extra bits that would likely be discarded at the receiver. In this manner, the variable-to-fixed scheme may limit the amount of signaling overhead.

Aspects of the present disclosure propose enhancements to a PAS based transmission schemes, by introducing Gray mapping in the PAS architecture. As will be described in greater detail below, utilizing Gray mapping in a PAS architecture can help increase the number of information bits that are likely to be received successfully at the receiver, which may result in a reduced number of transmissions.

### Introduction to Wireless Communication Networks

The techniques and methods described herein may be used for various wireless communications networks. While aspects may be described herein using terminology commonly associated with 3G, 4G, and/or 5G wireless technologies, aspects of the present disclosure may likewise be applicable to other communication systems and standards not explicitly mentioned herein.

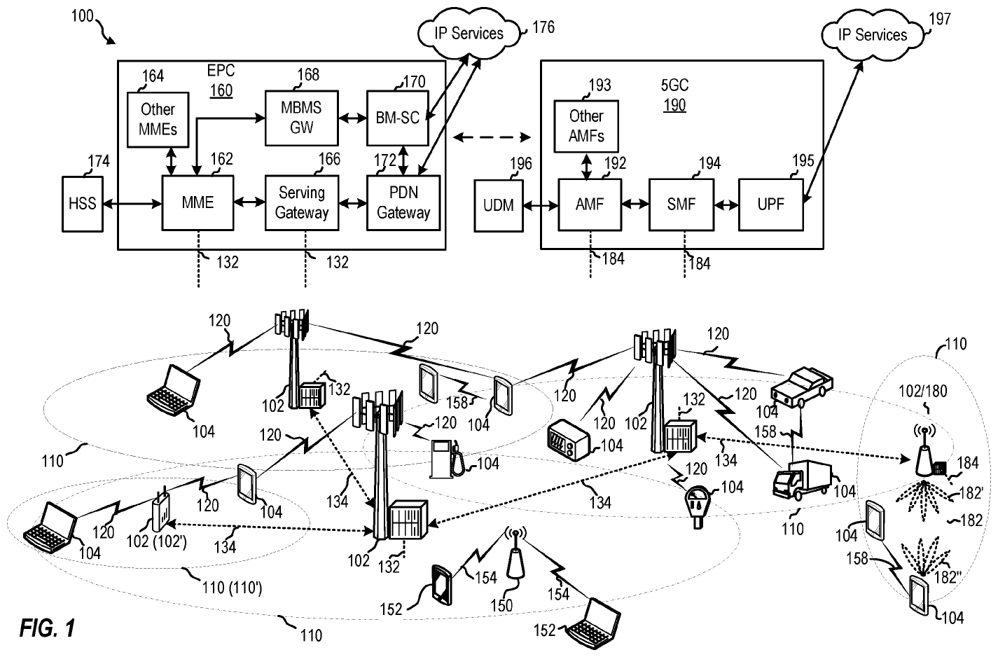

FIG. 1 depicts an example of a wireless communication network 100, in which aspects described herein may be implemented.

Generally, wireless communication network 100 includes various network entities (alternatively, network elements or network nodes). A network entity is generally a communications device and/or a communication function performed by a communications device. For example, various functions of a network as well as various devices associated with and interacting with a network may be considered network entities.

In the depicted example, wireless communication network 100 includes base stations (BSs) 102, user equipments (UEs) 104, and one or more core networks, such as an Evolved Packet Core (EPC) 160 and 5G Core (5GC) network 190, which interoperate to provide communications services over various communications links, including wired and wireless links.

FIG. 1 depicts various example UEs 104, which may more generally include: a cellular phone, smart phone, session initiation protocol (SIP) phone, laptop, personal digital assistant (PDA), satellite radio, global positioning system, multimedia device, video device, digital audio player, camera, game console, tablet, smart device, wearable device, vehicle, electric meter, gas pump, large or small kitchen appliance, healthcare device, implant, sensor/actuator, display, internet of things (IOT) devices, always on (AON) devices, edge processing devices, or other similar devices. UEs 104 may also be referred to more generally as a mobile device, a wireless device, a wireless communications device, a station, a mobile station, a subscriber station, a mobile subscriber station, a mobile unit, a subscriber unit, a wireless unit, a remote unit, a remote device, an access terminal, a mobile terminal, a wireless terminal, a remote terminal, a handset, and others.

BSs 102 wirelessly communicate with UEs 104 via communications links 120. The communication links 120 between BSs 102 and UEs 104 may include uplink (UL) (also referred to as reverse link) transmissions from a UE 104 to a BS 102 and/or downlink (DL) (also referred to as forward link) transmissions from a BS 102 to a UE 104. The communication links 120 may use multiple-input and multiple-output (MIMO) antenna technology, including spatial multiplexing, beamforming, and/or transmit diversity in various aspects.

BSs 102 may generally include: a NodeB, enhanced NodeB (eNB), next generation enhanced NodeB (ng-eNB), next generation NodeB (gNB or gNodeB), access point, base transceiver station, radio base station, radio transceiver, transceiver function, transmission reception point, and others. Each of BSs 102 may provide communication coverage for a respective geographic coverage area 110, which may sometimes be referred to as a cell, and which may overlap in some cases (e.g., small cell 102′ may have a coverage area 110′ that overlaps the coverage area 110 of a macro cell). A BS may, for example, provide communication coverage for a macro cell (covering relatively large geographic area), a pico cell (covering relatively smaller geographic area, such as a sports stadium), a femto cell (relatively smaller geographic area (e.g., a home)), and/or other types of cells.

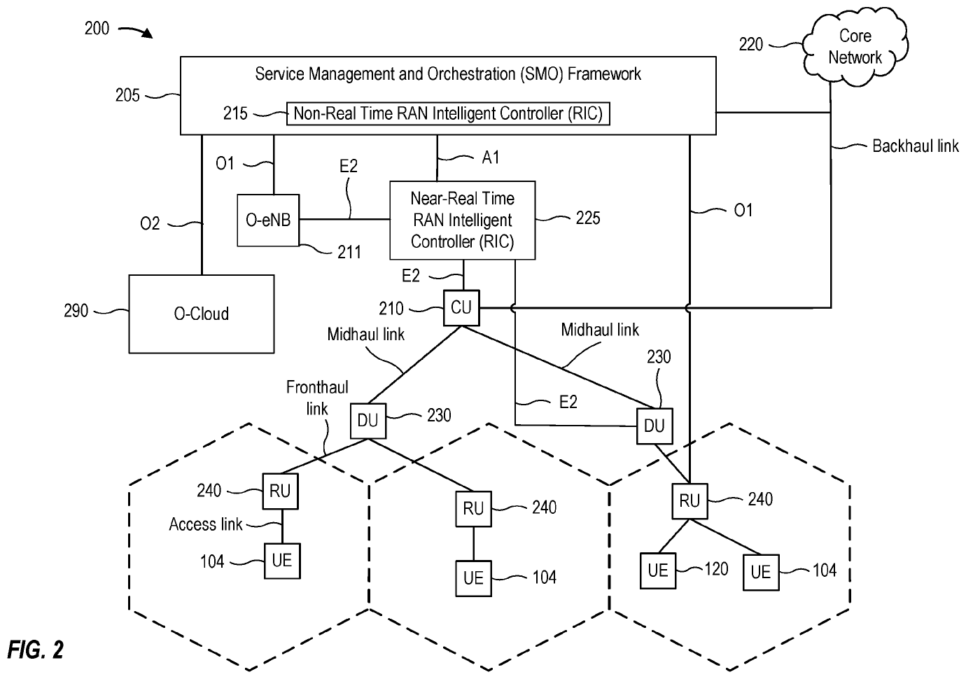

While BSs 102 are depicted in various aspects as unitary communications devices, BSs 102 may be implemented in various configurations. For example, one or more components of base station may be disaggregated, including a central unit (CU), one or more distributed units (DUs), one or more radio units (RUs), a radio unit (RU), a Near-Real Time (Near-RT) RAN Intelligent Controller (RIC), or a Non-Real Time (Non-RT) RIC, to name a few examples. In another example, various aspects of a base station may be virtualized. More generally, a base station (e.g., BS 102) may include components that are located at a single physical location or components located at various physical locations. In examples in which a base station includes components that are located at various physical locations, the various components may each perform functions such that, collectively, the various components achieve functionality that is similar to a base station that is located at a single physical location. In some aspects, a base station including components that are located at various physical locations may be referred to as a disaggregated radio access network architecture, such as an Open RAN (O-RAN) or Virtualized RAN (VRAN) architecture. FIG. 2 depicts and describes an example disaggregated base station architecture.

Different BSs 102 within wireless communication network 100 may also be configured to support different radio access technologies, such as 3G, 4G, and 5G. For example, BSs 102 configured for 4G LTE (collectively referred to as Evolved Universal Mobile Telecommunications System (UMTS) Terrestrial Radio Access Network (E-UTRAN)) may interface with the EPC 160 through first backhaul links 132 (e.g., an S1 interface). BSs 102 configured for 5G (e.g., 5G NR or Next Generation RAN (NG-RAN)) may interface with 5GC 190 through second backhaul links 184. BSs 102 may communicate directly or indirectly (e.g., through the EPC 160 or 5GC 190) with each other over third backhaul links 134 (e.g., X2 interface), which may be wired or wireless.

Wireless communication network 100 may subdivide the electromagnetic spectrum into various classes, bands, channels, or other features. In some aspects, the subdivision is provided based on wavelength and frequency, where frequency may also be referred to as a carrier, a subcarrier, a frequency channel, a tone, or a subband. For example, 3GPP currently defines Frequency Range 1 (FR1) as including 600 MHZ-6 GHz, which is often referred to (interchangeably) as “Sub-6 GHz”. Similarly, 3GPP currently defines Frequency Range 2 (FR2) as including 26-41 GHz, which is sometimes referred to (interchangeably) as a “millimeter wave” (“mmW” or “mmWave”). A base station configured to communicate using mmWave/near mmWave radio frequency bands (e.g., a mmWave base station such as BS 180) may utilize beamforming (e.g., 182) with a UE (e.g., 104) to improve path loss and range.

The communication links 120 between BSs 102 and, for example, UEs 104, may be through one or more carriers, which may have different bandwidths (e.g., 5, 10, 15, 20, 100, 400, and other MHz), and which may be aggregated in various aspects. Carriers may or may not be adjacent to each other. Allocation of carriers may be asymmetric with respect to DL and UL (e.g., more or fewer carriers may be allocated for DL than for UL).

Communications using higher frequency bands may have higher path loss and a shorter range compared to lower frequency communications. Accordingly, certain base stations (e.g., 180 in FIG. 1) may utilize beamforming 182 with a UE 104 to improve path loss and range. For example, BS 180 and the UE 104 may each include a plurality of antennas, such as antenna elements, antenna panels, and/or antenna arrays to facilitate the beamforming. In some cases, BS 180 may transmit a beamformed signal to UE 104 in one or more transmit directions 182′. UE 104 may receive the beamformed signal from the base station 180 in one or more receive directions 182″. UE 104 may also transmit a beamformed signal to the base station 180 in one or more transmit directions 182″. BS 180 may also receive the beamformed signal from UE 104 in one or more receive directions 182′. Base station 180 and UE 104 may then perform beam training to determine the best receive and transmit directions for each of BS 180 and UE 104. Notably, the transmit and receive directions for BS 180 may or may not be the same. Similarly, the transmit and receive directions for UE 104 may or may not be the same.

Wireless communication network 100 further includes a Wi-Fi AP 150 in communication with Wi-Fi stations (STAs) 152 via communication links 154 in, for example, a 2.4 GHz and/or 5 GHz unlicensed frequency spectrum.

Certain UEs 104 may communicate with each other using device-to-device (D2D) communication link 158. D2D communication link 158 may use one or more sidelink channels, such as a physical sidelink broadcast channel (PSBCH), a physical sidelink discovery channel (PSDCH), a physical sidelink shared channel (PSSCH), and a physical sidelink control channel (PSCCH).

EPC 160 may include various functional components, including: a Mobility Management Entity (MME) 162, other MMEs 164, a Serving Gateway 166, a Multimedia Broadcast Multicast Service (MBMS) Gateway 168, a Broadcast Multicast Service Center (BM-SC) 170, and a Packet Data Network (PDN) Gateway 172 in the depicted example. MME 162 may be in communication with a Home Subscriber Server (HSS) 174. MME 162 is the control node that processes the signaling between the UEs 104 and the EPC 160. Generally, MME 162 provides bearer and connection management.

Generally, user Internet protocol (IP) packets are transferred through Serving Gateway 166, which itself is connected to PDN Gateway 172. PDN Gateway 172 provides UE IP address allocation as well as other functions. PDN Gateway 172 and the BM-SC 170 are connected to IP Services 176, which may include, for example, the Internet, an intranet, an IP Multimedia Subsystem (IMS), a Packet Switched (PS) streaming service, and/or other IP services.

BM-SC 170 may provide functions for MBMS user service provisioning and delivery. BM-SC 170 may serve as an entry point for content provider MBMS transmission, may be used to authorize and initiate MBMS Bearer Services within a public land mobile network (PLMN), and may be used to schedule MBMS transmissions. MBMS Gateway 168 may be used to distribute MBMS traffic to the BSs 102 belonging to a Multicast Broadcast Single Frequency Network (MBSFN) area broadcasting a particular service, and may be responsible for session management (start/stop) and for collecting eMBMS related charging information.

5GC 190 may include various functional components, including: an Access and Mobility Management Function (AMF) 192, other AMFs 193, a Session Management Function (SMF) 194, and a User Plane Function (UPF) 195. AMF 192 may be in communication with Unified Data Management (UDM) 196.

AMF 192 is a control node that processes signaling between UEs 104 and 5GC 190. AMF 192 provides, for example, quality of service (QoS) flow and session management.

Internet protocol (IP) packets are transferred through UPF 195, which is connected to the IP Services 197, and which provides UE IP address allocation as well as other functions for 5GC 190. IP Services 197 may include, for example, the Internet, an intranet, an IMS, a PS streaming service, and/or other IP services.

In various aspects, a network entity or network node can be implemented as an aggregated base station, as a disaggregated base station, an integrated access and backhaul (IAB) node, a relay node, a sidelink node, to name a few examples.

FIG. 2 depicts an example disaggregated base station 200 architecture. The disaggregated base station 200 architecture may include one or more central units (CUs) 210 that can communicate directly with a core network 220 via a backhaul link, or indirectly with the core network 220 through one or more disaggregated base station units (such as a Near-Real Time (Near-RT) RAN Intelligent Controller (RIC) 225 via an E2 link, or a Non-Real Time (Non-RT) RIC 215 associated with a Service Management and Orchestration (SMO) Framework 205, or both). A CU 210 may communicate with one or more distributed units (DUs) 230 via respective midhaul links, such as an F1 interface. The DUs 230 may communicate with one or more radio units (RUS) 240 via respective fronthaul links. The RUs 240 may communicate with respective UEs 104 via one or more radio frequency (RF) access links. In some implementations, the UE 104 may be simultaneously served by multiple RUs 240.

Each of the units, e.g., the CUS 210, the DUs 230, the RUs 240, as well as the Near-RT RICs 225, the Non-RT RICs 215 and the SMO Framework 205, may include one or more interfaces or be coupled to one or more interfaces configured to receive or transmit signals, data, or information (collectively, signals) via a wired or wireless transmission medium. Each of the units, or an associated processor or controller providing instructions to the communication interfaces of the units, can be configured to communicate with one or more of the other units via the transmission medium. For example, the units can include a wired interface configured to receive or transmit signals over a wired transmission medium to one or more of the other units. Additionally, the units can include a wireless interface, which may include a receiver, a transmitter or transceiver (such as a radio frequency (RF) transceiver), configured to receive or transmit signals, or both, over a wireless transmission medium to one or more of the other units.

In some aspects, the CU 210 may host one or more higher layer control functions. Such control functions can include radio resource control (RRC), packet data convergence protocol (PDCP), service data adaptation protocol (SDAP), or the like. Each control function can be implemented with an interface configured to communicate signals with other control functions hosted by the CU 210. The CU 210 may be configured to handle user plane functionality (e.g., Central Unit-User Plane (CU-UP)), control plane functionality (e.g., Central Unit-Control Plane (CU-CP)), or a combination thereof. In some implementations, the CU 210 can be logically split into one or more CU-UP units and one or more CU-CP units. The CU-UP unit can communicate bidirectionally with the CU-CP unit via an interface, such as the E1 interface when implemented in an O-RAN configuration. The CU 210 can be implemented to communicate with the DU 230, as necessary, for network control and signaling.

The DU 230 may correspond to a logical unit that includes one or more base station functions to control the operation of one or more RUs 240. In some aspects, the DU 230 may host one or more of a radio link control (RLC) layer, a medium access control (MAC) layer, and one or more high physical (PHY) layers (such as modules for forward error correction (FEC) encoding and decoding, scrambling, modulation and demodulation, or the like) depending, at least in part, on a functional split, such as those defined by the 3rd Generation Partnership Project (3GPP). In some aspects, the DU 230 may further host one or more low PHY layers. Each layer (or module) can be implemented with an interface configured to communicate signals with other layers (and modules) hosted by the DU 230, or with the control functions hosted by the CU 210.

Lower-layer functionality can be implemented by one or more RUs 240. In some deployments, an RU 240, controlled by a DU 230, may correspond to a logical node that hosts RF processing functions, or low-PHY layer functions (such as performing fast Fourier transform (FFT), inverse FFT (iFFT), digital beamforming, physical random access channel (PRACH) extraction and filtering, or the like), or both, based at least in part on the functional split, such as a lower layer functional split. In such an architecture, the RU(s) 240 can be implemented to handle over the air (OTA) communication with one or more UEs 104. In some implementations, real-time and non-real-time aspects of control and user plane communication with the RU(s) 240 can be controlled by the corresponding DU 230. In some scenarios, this configuration can enable the DU(s) 230 and the CU 210 to be implemented in a cloud-based RAN architecture, such as a vRAN architecture.

The SMO Framework 205 may be configured to support RAN deployment and provisioning of non-virtualized and virtualized network elements. For non-virtualized network elements, the SMO Framework 205 may be configured to support the deployment of dedicated physical resources for RAN coverage requirements which may be managed via an operations and maintenance interface (such as an O1 interface). For virtualized network elements, the SMO Framework 205 may be configured to interact with a cloud computing platform (such as an open cloud (O-Cloud) 290) to perform network element life cycle management (such as to instantiate virtualized network elements) via a cloud computing platform interface (such as an O2 interface). Such virtualized network elements can include, but are not limited to, CUs 210, DUs 230, RUs 240 and Near-RT RICs 225. In some implementations, the SMO Framework 205 can communicate with a hardware aspect of a 4G RAN, such as an open eNB (O-eNB) 211, via an O1 interface. Additionally, in some implementations, the SMO Framework 205 can communicate directly with one or more RUs 240 via an O1 interface. The SMO Framework 205 also may include a Non-RT RIC 215 configured to support functionality of the SMO Framework 205.

The Non-RT RIC 215 may be configured to include a logical function that enables non-real-time control and optimization of RAN elements and resources, Artificial Intelligence/Machine Learning (AI/ML) workflows including model training and updates, or policy-based guidance of applications/features in the Near-RT RIC 225. The Non-RT RIC 215 may be coupled to or communicate with (such as via an A1 interface) the Near-RT RIC 225. The Near-RT RIC 225 may be configured to include a logical function that enables near-real-time control and optimization of RAN elements and resources via data collection and actions over an interface (such as via an E2 interface) connecting one or more CUs 210, one or more DUs 230, or both, as well as an O-eNB, with the Near-RT RIC 225.

In some implementations, to generate AI/ML models to be deployed in the Near-RT RIC 225, the Non-RT RIC 215 may receive parameters or external enrichment information from external servers. Such information may be utilized by the Near-RT RIC 225 and may be received at the SMO Framework 205 or the Non-RT RIC 215 from non-network data sources or from network functions. In some examples, the Non-RT RIC 215 or the Near-RT RIC 225 may be configured to tune RAN behavior or performance. For example, the Non-RT RIC 215 may monitor long-term trends and patterns for performance and employ AI/ML models to perform corrective actions through the SMO Framework 205 (such as reconfiguration via 01) or via creation of RAN management policies (such as A1 policies).

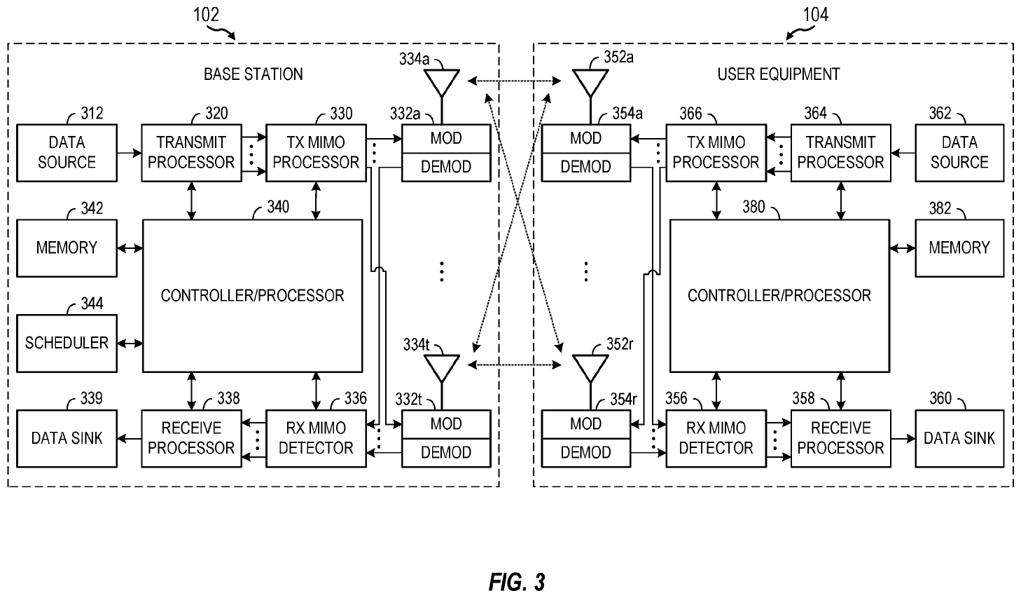

FIG. 3 depicts aspects of an example BS 102 and a UE 104.

Generally, BS 102 includes various processors (e.g., 320, 330, 338, and 340), antennas 334a-t (collectively 334), transceivers 332a-t (collectively 332), which include modulators and demodulators, and other aspects, which enable wireless transmission of data (e.g., data source 312) and wireless reception of data (e.g., data sink 339). For example, BS 102 may send and receive data between BS 102 and UE 104. BS 102 includes controller/processor 340, which may be configured to implement various functions described herein related to wireless communications.

Generally, UE 104 includes various processors (e.g., 358, 364, 366, and 380), antennas 352a-r (collectively 352), transceivers 354a-r (collectively 354), which include modulators and demodulators, and other aspects, which enable wireless transmission of data (e.g., data source 362) and wireless reception of data (e.g., data sink 360). UE 104 includes controller/processor 380, which may be configured to implement various functions described herein related to wireless communications.

In regards to an example downlink transmission, BS 102 includes a transmit processor 320 that may receive data from a data source 312 and control information from a controller/processor 340. The control information may be for the physical broadcast channel (PBCH), physical control format indicator channel (PCFICH), physical HARQ indicator channel (PHICH), physical downlink control channel (PDCCH), group common PDCCH (GC PDCCH), and others. The data may be for the physical downlink shared channel (PDSCH), in some examples.

Transmit processor 320 may process (e.g., encode and symbol map) the data and control information to obtain data symbols and control symbols, respectively. Transmit processor 320 may also generate reference symbols, such as for the primary synchronization signal (PSS), secondary synchronization signal (SSS), PBCH demodulation reference signal (DMRS), and channel state information reference signal (CSI-RS).

Transmit (Tx) multiple-input multiple-output (MIMO) processor 330 may perform spatial processing (e.g., precoding) on the data symbols, the control symbols, and/or the reference symbols, if applicable, and may provide output symbol streams to the modulators (MODs) in transceivers 332a-332t. Each modulator in transceivers 332a-332t may process a respective output symbol stream to obtain an output sample stream. Each modulator may further process (e.g., convert to analog, amplify, filter, and upconvert) the output sample stream to obtain a downlink signal. Downlink signals from the modulators in transceivers 332a-332t may be transmitted via the antennas 334a-334t, respectively.

In order to receive the downlink transmission, UE 104 includes antennas 352a-352r that may receive the downlink signals from the BS 102 and may provide received signals to the demodulators (DEMODs) in transceivers 354a-354r, respectively. Each demodulator in transceivers 354a-354r may condition (e.g., filter, amplify, downconvert, and digitize) a respective received signal to obtain input samples. Each demodulator may further process the input samples to obtain received symbols.

MIMO detector 356 may obtain received symbols from all the demodulators in transceivers 354a-354r, perform MIMO detection on the received symbols if applicable, and provide detected symbols. Receive processor 358 may process (e.g., demodulate, deinterleave, and decode) the detected symbols, provide decoded data for the UE 104 to a data sink 360, and provide decoded control information to a controller/processor 380.

In regards to an example uplink transmission, UE 104 further includes a transmit processor 364 that may receive and process data (e.g., for the PUSCH) from a data source 362 and control information (e.g., for the physical uplink control channel (PUCCH)) from the controller/processor 380. Transmit processor 364 may also generate reference symbols for a reference signal (e.g., for the sounding reference signal (SRS)). The symbols from the transmit processor 364 may be precoded by a Tx MIMO processor 366 if applicable, further processed by the modulators in transceivers 354a-354r (e.g., for SC-FDM), and transmitted to BS 102.

At BS 102, the uplink signals from UE 104 may be received by antennas 334a-t, processed by the demodulators in transceivers 332a-332t, detected by a MIMO detector 336 if applicable, and further processed by a receive processor 338 to obtain decoded data and control information sent by UE 104. Receive processor 338 may provide the decoded data to a data sink 339 and the decoded control information to the controller/processor 340.

Memories 342 and 382 may store data and program codes for BS 102 and UE 104, respectively.

Scheduler 344 may schedule UEs for data transmission on the downlink and/or uplink.

In various aspects, BS 102 may be described as transmitting and receiving various types of data associated with the methods described herein. In these contexts, “transmitting” may refer to various mechanisms of outputting data, such as outputting data from data source 312, scheduler 344, memory 342, transmit processor 320, controller/processor 340, Tx MIMO processor 330, transceivers 332a-t, antenna 334a-t, and/or other aspects described herein. Similarly, “receiving” may refer to various mechanisms of obtaining data, such as obtaining data from antennas 334a-t, transceivers 332a-t, Rx MIMO detector 336, controller/processor 340, receive processor 338, scheduler 344, memory 342, and other aspects described herein.

In various aspects, UE 104 may likewise be described as transmitting and receiving various types of data associated with the methods described herein. In these contexts, “transmitting” may refer to various mechanisms of outputting data, such as outputting data from data source 362, memory 382, transmit processor 364, controller/processor 380, Tx MIMO processor 366, transceivers 354a-t, antenna 352a-t, and/or other aspects described herein. Similarly, “receiving” may refer to various mechanisms of obtaining data, such as obtaining data from antennas 352a-t, transceivers 354a-t, Rx MIMO detector 356, controller/processor 380, receive processor 358, memory 382, and other aspects described herein.

In some aspects, a processor may be configured to perform various operations, such as those associated with the methods described herein, and transmit (output) to or receive (obtain) data from another interface that is configured to transmit or receive, respectively, the data.

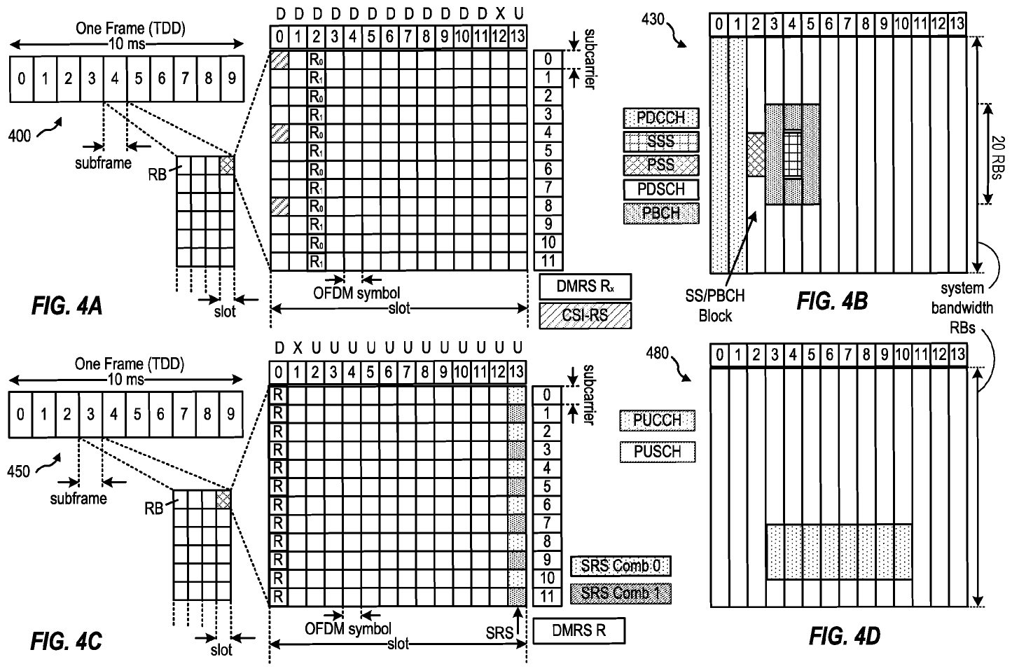

FIGS. 4A, 4B, 4C, and 4D depict aspects of data structures for a wireless communication network, such as wireless communication network 100 of FIG. 1.

In particular, FIG. 4A is a diagram 400 illustrating an example of a first subframe within a 5G (e.g., 5G NR) frame structure, FIG. 4B is a diagram 430 illustrating an example of DL channels within a 5G subframe, FIG. 4C is a diagram 450 illustrating an example of a second subframe within a 5G frame structure, and FIG. 4D is a diagram 480 illustrating an example of UL channels within a 5G subframe.

Wireless communication systems may utilize orthogonal frequency division multiplexing (OFDM) with a cyclic prefix (CP) on the uplink and downlink. Such systems may also support half-duplex operation using time division duplexing (TDD). OFDM and single-carrier frequency division multiplexing (SC-FDM) partition the system bandwidth (e.g., as depicted in FIGS. 4B and 4D) into multiple orthogonal subcarriers. Each subcarrier may be modulated with data. Modulation symbols may be sent in the frequency domain with OFDM and in the time domain with SC-FDM.

A wireless communication frame structure may be frequency division duplex (FDD), in which for a particular set of subcarriers and subframes within the set of subcarriers are dedicated for either DL or UL. Wireless communication frame structures may also be time division duplex (TDD), in which for a particular set of subcarriers and subframes within the set of subcarriers are dedicated for both DL and UL.

In FIGS. 4A and 4C, the wireless communication frame structure is TDD where Dis DL, U is UL, and X is flexible for use between DL/UL. UEs may be configured with the slot format through a received slot format indicator (SFI) (dynamically through DL control information (DCI), or semi-statically/statically through radio resource control (RRC) signaling). In the depicted examples, a 10 ms frame is divided into 10 equally sized 1 ms subframes. Each subframe may include one or more time slots. In some examples, each slot may include 7 or 14 symbols, depending on the slot configuration. Subframes may also include mini-slots, which generally have fewer symbols than an entire slot. Other wireless communication technologies may have a different frame structure and/or different channels.

Generally, the number of slots within a subframe is based on a slot configuration and a numerology. For slot configuration 0, different numerologies (μ) 0 to 5 allow for 1, 2, 4, 8, 16, and 32 slots, respectively, per subframe. For slot configuration 1, different numerologies 0 to 2 allow for 2, 4, and 8 slots, respectively, per subframe. Accordingly, for slot configuration 0 and numerology μ, there are 14 symbols/slot and 2μ slots/subframe. The subcarrier spacing and symbol length/duration are a function of the numerology. The subcarrier spacing may be equal to 24× 15 kHz, where u is the numerology 0 to 5. As such, the numerology μ=0 has a subcarrier spacing of 15 kHz and the numerology μ=5 has a subcarrier spacing of 480 kHz. The symbol length/duration is inversely related to the subcarrier spacing. FIGS. 4A, 4B, 4C, and 4D provide an example of slot configuration 0 with 14 symbols per slot and numerology μ=2 with 4 slots per subframe. The slot duration is 0.25 ms, the subcarrier spacing is 60 kHz, and the symbol duration is approximately 16.67 μs.

As depicted in FIGS. 4A, 4B, 4C, and 4D, a resource grid may be used to represent the frame structure. Each time slot includes a resource block (RB) (also referred to as physical RBs (PRBs)) that extends 12 consecutive subcarriers. The resource grid is divided into multiple resource elements (REs). The number of bits carried by each RE depends on the modulation scheme.

As illustrated in FIG. 4A, some of the REs carry reference (pilot) signals (RS) for a UE (e.g., UE 104 of FIGS. 1 and 3). The RS may include demodulation RS (DMRS) and channel state information reference signals (CSI-RS) for channel estimation at the UE. The RS may also include beam measurement RS (BRS), beam refinement RS (BRRS), and phase tracking RS (PT-RS).

FIG. 4B illustrates an example of various DL channels within a subframe of a frame. The physical downlink control channel (PDCCH) carries DCI within one or more control channel elements (CCEs), each CCE including nine RE groups (REGs), each REG including four consecutive REs in an OFDM symbol.

A primary synchronization signal (PSS) may be within symbol 2 of particular subframes of a frame. The PSS is used by a UE (e.g., 104 of FIGS. 1 and 3) to determine subframe/symbol timing and a physical layer identity.

A secondary synchronization signal (SSS) may be within symbol 4 of particular subframes of a frame. The SSS is used by a UE to determine a physical layer cell identity group number and radio frame timing.

Based on the physical layer identity and the physical layer cell identity group number, the UE can determine a physical cell identifier (PCI). Based on the PCI, the UE can determine the locations of the aforementioned DMRS. The physical broadcast channel (PBCH), which carries a master information block (MIB), may be logically grouped with the PSS and SSS to form a synchronization signal (SS)/PBCH block. The MIB provides a number of RBs in the system bandwidth and a system frame number (SFN). The physical downlink shared channel (PDSCH) carries user data, broadcast system information not transmitted through the PBCH such as system information blocks (SIBs), and paging messages.

As illustrated in FIG. 4C, some of the REs carry DMRS (indicated as R for one particular configuration, but other DMRS configurations are possible) for channel estimation at the base station. The UE may transmit DMRS for the PUCCH and DMRS for the PUSCH. The PUSCH DMRS may be transmitted, for example, in the first one or two symbols of the PUSCH. The PUCCH DMRS may be transmitted in different configurations depending on whether short or long PUCCHs are transmitted and depending on the particular PUCCH format used. UE 104 may also transmit sounding reference signals (SRS). The SRS may be transmitted, for example, in the last symbol of a subframe. The SRS may have a comb structure, and a UE may transmit SRS on one of the combs. The SRS may be used by a base station for channel quality estimation to enable frequency-dependent scheduling on the UL.

FIG. 4D illustrates an example of various UL channels within a subframe of a frame. The PUCCH may be located as indicated in one configuration. The PUCCH carries uplink control information (UCI), such as scheduling requests, a channel quality indicator (CQI), a precoding matrix indicator (PMI), a rank indicator (RI), and HARQ ACK/NACK feedback. The PUSCH carries data, and may additionally be used to carry a buffer status report (BSR), a power headroom report (PHR), and/or UCI.

### Example Probabilistic Amplitude Shaping Architecture

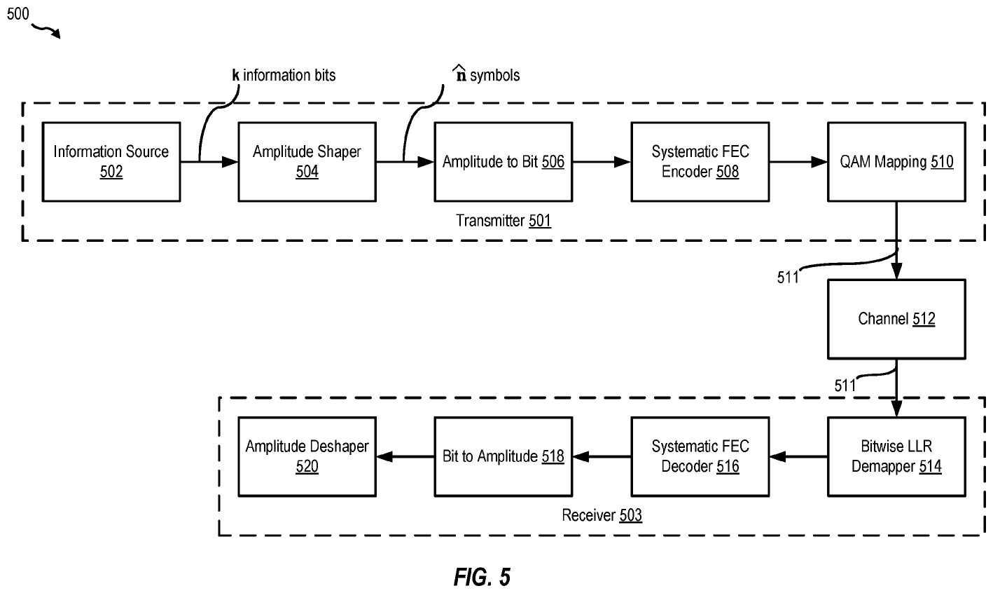

FIG. 5 illustrates a communication system employing probabilistic amplitude shaping. Probabilistic amplitude shaping (PAS) utilizes reverse concatenation whereby the shaping precedes FEC coding.

The communication system 500 includes a wireless transmitter 501 and a wireless receiver 503. For example, an information source 502 may generate k information bits that is received by an amplitude shaper 504. The amplitude shaper 504 may generate a sequence of symbols (e.g., n symbols in a fixed-to-fixed scheme or \hat{n} symbols in a variable-to-fixed scheme). The sequence of symbols (n symbols or ñ symbols) may be received by an amplitude to bit component 506 and then an FEC encoder 508 to produce a set of bits. In some examples, some of the bits are shaped and others are uniformly distributed. After the encoding, the bits are mapped, e.g., to quadrature amplitude modulation (QAM) symbols by a QAM mapping component 510. A signal 511 (e.g., the symbols) is then transmitted over the wireless medium to the wireless receiver 503, e.g., over a channel 512.

At the wireless receiver 503, the signal 511 is received by a bitwise log-likelihood ratios (LLR) demapper component 514 to demap the symbols of the signal 511. The demapped symbols are received by the FEC decoder 516 and then a bit to amplitude component 518 to decode the bits. The decoded bits are provided to an amplitude deshaper 520 to distribute the received bits (e.g., uniformly), which may then be sent to their destination.

Amplitude shaper 504 can also be known as or an implementation of a distribution matcher. In some aspects, a distribution matcher includes a decompressor (e.g., a decoder) to convert a sequence of information bits (u) into a set of symbols. The sequence of information bits (u) may be uniformly distributed. In an example, in 5G NR, the sequence of information bits may be uniformly distributed. The decompressor may generate the sequence of symbols based on a target probability mass function (PMF), such as a Maxwell-Boltzmann Distribution, and a symbol block length (n). The sequence of symbols may be transmitted to a receiver for processing to determine the transmitted information.

The distribution matcher may also include a compressor (e.g., an encoder) to convert the set of symbols into a sequence of compressed information bits (û). In a fixed-to-fixed scheme, the distribution matcher may include a comparator to compare the sequence of information bits (u) to the sequence of compressed information bits (û) to determine how many information bits were not converted into the set of symbols. In some examples, the distribution matcher may provide the output of the comparator to the receiver so that the receiver can determine how to process the set of symbols. For example, based on a compressor at the receiver, the receiver may compress the set of symbols to generate information bits based on the target PMF, which may result in extra bits. The receiver may use the output of the comparator (e.g., discard signaling) to determine how many bits to discard.

Alternatively, the distribution matcher may employ a variable-to-fixed scheme in which the decompressor is configured with a “back-off” limit. The back-off limit may limit the amount of information bits that the decompressor may convert to the set of symbols so that extra bits are not transmitted to the receiver for discarding. Moreover, the variable-to-fixed scheme may limit the amount of overhead (e.g., compared to the fixed-to-fixed scheme) as a comparator is not needed and, thus, the distribution matcher may forego transmitting discard signaling with information about the number of bits to discard at the receiver. In such examples, when employing the variable-to-fixed scheme, the rate loss compared to target entropy may be improved compared to when employing the fixed-to-fixed scheme.

### Example Amplitude Shaper and Amplitude Deshaper in a Variable-to-Fixed Scheme

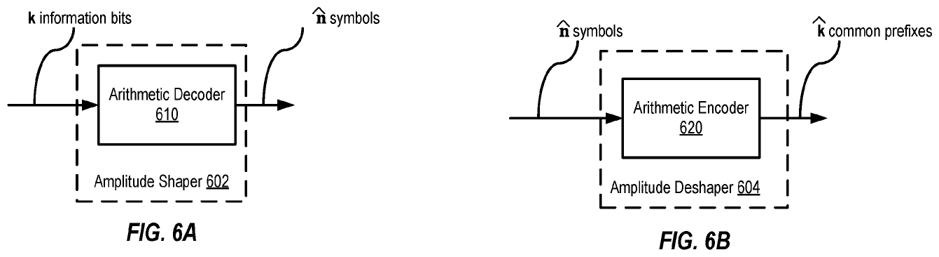

FIG. 6A illustrates an example of an amplitude shaper 602 that may be used in an independently and identically distributed (IID) variable-to-fixed distribution matching scheme.

As illustrated, amplitude shaper 602 may be implemented using an arithmetic decoder 610. The arithmetic decoder 610 may be configured to take a block of k information bits and generate a sequence of shaped symbols. The arithmetic decoder may be configured to achieve a target distribution p over a symbol alphabet (e.g., including numerical values such as integers) [symbol] ={a₁, a₂, . . . , aₘ} with a fixed entropy Hₚ. Parameters \hat{n} and η may be predetermined and:

$$k = ( ⌈ {H}_{p} ⌉ + η ) \cdot \hat{n} .$$

The arithmetic decoder may be implemented using a mapping function:

$$: [ 0 , 1 ) \to {𝒜}^{\hat{n}} ,$$

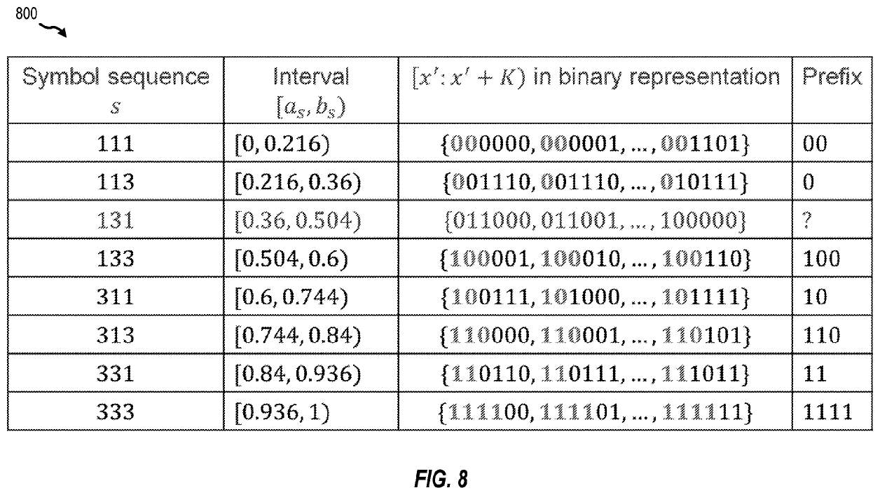

Each symbol sequence of length \hat{n} may be associated with an interval [aₛ, bₛ)↓[0, 1) such that Pr({s})=bₛ−aₛ and that all such intervals are disjoint. For a numerical valueu ∈[0, 1), [symbol] (u)=s if and only if u∈[aₛ, bₛ). For example, k information bits (x_{K-1}, . . . , x₁, x₀) with an integer representation x=Σᵢxᵢ2ⁱ may be encoded to [symbol] (2^{-k}x). Example symbol sequences, corresponding intervals, and binary representations are shown in FIG. 8.

As illustrated in FIG. 6B, an amplitude deshaper 604 may be implemented using an arithmetic encoder 620, which may perform the reverse order of the processing of the amplitude shaper 602. For example, the arithmetic encoder 620 can take a sequence of \hat{n} symbols and determine a number of information bits.

The arithmetic encoder may be implemented using a mapping: [symbol] [symbol] →{0, 1, . . . , 2^{k}−1}×{0, 1, . . . , 2^{k}−1}. For each symbol sequence s of length \hat{n}, a whole collection of integers [x′: x′+K)={x′, x′+1, . . . , x′+K−1} of K integers may all be encoded to s by the mapping [symbol] whenever [x′: x′+K)⊆2^{k}[aₛ, bₛ) holds, where x′ is a integer representation of a block of k information bits, where integer K is:

$$\begin{matrix}K = ⌈ {2}^{k} ( {b}_{s} - {a}_{s} ) ⌉ ; or \\ K = ⌈ {2}^{k} ( {b}_{s} - {a}_{s} ) ⌉ - 1 .\end{matrix}$$

The symbol sequence s, if received correctly, corresponds to [symbol] (s)=(x′, K) dependent on the mapping [symbol] . The arithmetic encoder may use [symbol] (s)=(x′, K) to determine a quantity \hat{k} as the number of common prefixes of all binary representations of the integers in[x′: x′+K). These common prefixes can be used to carry \hat{k} out of k bits, via a first transmission of x. Examples of \hat{k} common prefixes are shown in FIG. 8.

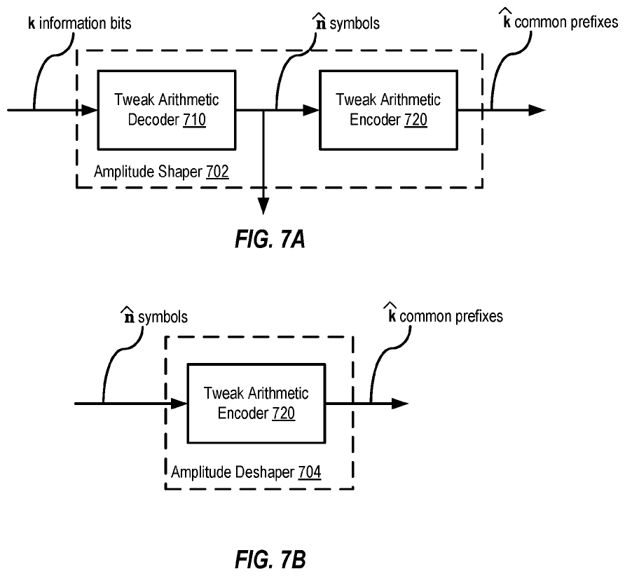

FIG. 7A illustrates an example amplitude shaper 702 that includes two modules: an arithmetic decoder 710 and an arithmetic encoder 720. The arithmetic decoder 710 may follow the IID variable-to-fixed distribution matching, similar to the arithmetic decoder 610 shown in FIG. 6. For example, tweak arithmetic decoder 710 can take k information bits as input and generate a sequence of \hat{n} shaped symbols.

The sequence of \hat{n} shaped symbols can also be input to the arithmetic encoder 720. The arithmetic encoder 720 can follow the IID variable-to-fixed distribution matching similar to the arithmetic encoder 620 shown in FIG. 6 and may be used to efficiently compute the \hat{k} common prefixes of all binary representations of the integers in [x′: x′+K).

In some aspects, the k-\hat{k} bits that belong to the original k information bits but are not the common prefixes are kept at the amplitude shaper 710 and are combined with another \hat{k} information bits for a next transmission.

As illustrated in FIG. 7B, an amplitude deshaper 704 may be implemented using the same arithmetic encoder 720 as amplitude shaper 702. Thus, a sequence of \hat{n} shaped symbols can also be input to the tweak arithmetic encoder 720 to recover \hat{k} common prefixes. The remaining k-\hat{k} bits that are not common prefixes may be discarded at the amplitude deshaper 704.

One potential issue in using the amplitude shaper and deshaper shown in FIGS. 7A and 7B is that, for some symbol sequences, there may be no common prefixes (\hat{k}=0). In such cases, the amplitude deshaper may not be able to uniquely determine a single bit of the k information bits.

An example of this occurrence is shown in the example table 800 of FIG. 8 that shows common prefixes for binary representations of the integers in [x′: x′+K), assuming the following set of parameters: [symbol] ={1, 3}, p(1)=0.6, p(3)=0.4, Hₚ=0.673, η=1, \hat{n}=3, k=┌Hₚ┐+η)·\hat{η}=(1+1)·3=6.

The first row of the table is the header, where each column of the header defines the variable in the following rows. For example, the first column of the table shows symbol sequence s of length \hat{n}, the second column shows the disjoint intervals as described in FIGS. 6A-B, the third column shows the collection of K integers in standard binary representation (also known as K binary numbers) as described in FIGS. 6A-B, where the particular integers in the collection depend on the underlying symbol sequence s, and the fourth column shows the corresponding common prefixes.

For example, if the symbol sequence s=111, an arithmetic encoder can generate a collection of K binary numbers, which can be found in the third column of the second row. All of the K integers generated based on symbol sequence s=111 share the same two most significant bits, shown as the bolded two leading zeroes. The arithmetic encoder can determine the k common prefixes as two leading zeroes, 00, whereas \hat{k}=2.

In the illustrated example, the arithmetic encoder can determine at least some common prefixes for of the other symbol sequences, except symbol sequence s=131. Symbol sequence s=131 is an example sequence that the arithmetic encoder cannot determine common prefixes, as illustrated in the fourth row of table 800. Since there is no shared leading bits in the K binary numbers, there is no common prefix (\hat{k}=0). Such sequences can pose a challenge to arithmetic encoder as it is not possible to utilize (e.g., carry out) information bits from such sequences.

### Example Gray Coding for Variable-to-Fixed Distribution Matching

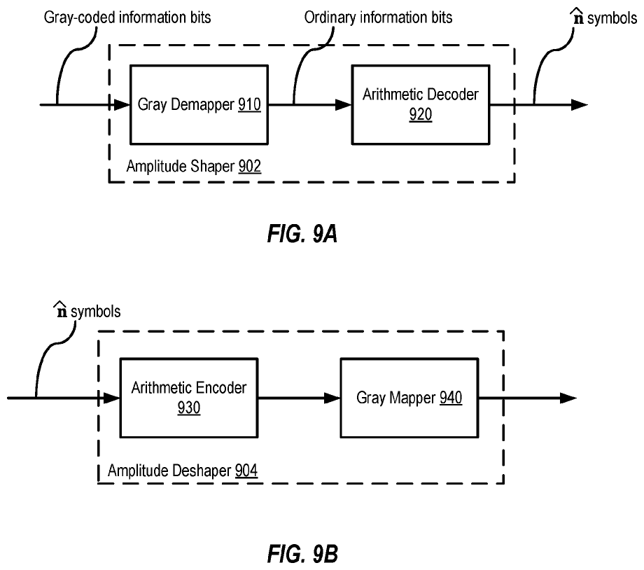

Aspects of the present disclosure, however, may help avoid the scenario where there are no common prefixes, by introducing Gray mapping in the PAS architecture for variable-to-fixed distribution matching. As will be described in greater detail below, utilizing Gray mapping may help ensure there are at least some common positions with no discrepancies, thereby increasing the number of information bits that are likely to be received successfully at the receiver and reducing the overall number of transmissions needed to convey k information bits. Details regarding determining positions with discrepancies can be found below with respect to FIG. 9B.

FIG. 9A illustrates an example amplitude shaper 902 that includes a Gray demapper 910 followed by an arithmetic decoder 920. Similarly, FIG. 9B illustrates an example amplitude deshaper 904 that includes a Gray mapper 940 after an arithmetic encoder 930.

The amplitude shaper of FIG. 9A may take a k-bit information sequence with integer representation y as input. The Gray demapper may form an integer x, where x=Ψ⁻¹(y). The arithmetic decoder may form the symbol sequence s= [symbol] (2^{-k}x) of length \hat{n}. This symbol sequence s is the output of the amplitude shaper.

For an integer y∈[0: 2^{k}), the binary representation may be (y_{K-1}, . . . , y₁, y₀).

The inverse Gray mapping Ψ⁻¹: [0: 2^{k})→[0: 2^{k}) can be defined by setting x=−Ψ⁻¹(y), where the integer x has binary representation (x_{K-1}, . . . , x₁, x₀). For every position index i∈{0, 1, . . . , k−1}, it may hold that xᵢ=yᵢ+yᵢ₊₁+ . . . +yₖ₋₁ with the summation over [symbol] . The definition of Ψ⁻¹ can be extended to subsets of [0: 2^{k}) by pointwise application of Ψ⁻¹.

For simplicity, in the following discussion, the integer x is treated as a proxy of the binary representation (x_{K-1}, . . . , x₁, x₀) whereas integer y is treated as a proxy to binary representation (y_{K-1}, . . . , y₁, y₀). In other words, Gray mapping Ψ and inverse Gray mapping Ψ⁻¹ can be applied directly to the binary representations. For example, following the definitions above, (y_{K-1}, . . . , y₁>y₀)=Ψ((x_{K-1}, . . . , x₁, x₀)) whereas (x_{K-1}, . . . , x₁, x₀)=Ψ⁻¹((y_{K-1}, . . . , y₁, y₀)).

In an example, using the parameters introduced with respect to FIG. 8, integer y=21 is the input to the amplitude shaper 902. Binary representation of integer y is information sequence (0, 1, 0, 1, 0, 1). Gray demapper 910 forms x=Ψ⁻¹(y)=25, where binary representation of x as the sequence of Gray demapped information bits is (0, 1, 1, 0, 0, 1) and the quantity (e.g., length or size) of information bits k is 6. In this example, arithmetic decoder 920 forms the symbol sequence s= [symbol] (2⁻⁶x)=(1, 3, 1) for transmission. As illustrated in FIG. 9B, amplitude deshaper 904 can include arithmetic encoder 930 and Gray mapper 940. Symbol sequence s of length \hat{n} (e.g., the output of amplitude shaper 902) can be the input to the amplitude deshaper 904. Arithmetic encoder 930 can take symbol sequence s as input and determine [symbol] (s)=(x′, K) based on symbol sequence s.

The Gray mapper 940 can determine the set [symbol] (Ψ) of all discrepancy positions of the set Ψ([x′: x′+K)), which is the set of all Gray-coded K numbers.

For any set of integer S⊆[0: 2^{k}), a position index i∈{0, 1, . . . , k−1} may be considered a discrepancy position of S if and only if there exist u and v in S such that under the binary representation of u and v, it holds that uᵢ≠vᵢ. In other words, if the binary representations of any two integers in S have a different bit on a given position index, the position index is a discrepancy position of S.

The Gray mapper 940 can pick any y∈Ψ([x′: x′+K)) and output all bits yᵢ with i∈{0, 1, . . . , k−1}\ [symbol] (Ψ). The cardinality of {0, 1, . . . , k−1}\ [symbol] (Ψ) is denoted by \hat{k}, which represents the number of bits transmitted without discrepancy. These \hat{k} positions with no discrepancy in Ψ([x′: x′+K)) are used to carry \hat{k} out of k information bits.

In an example, using the parameters introduced with respect to FIG. 8, symbol sequence s=(1, 3, 1) is the input to amplitude deshaper 904. Arithmetic encoder 930 can generate [symbol] (s)=(24, 9), where the collection of integers is [24: 24+9)={24, 25, 26, 27, 28, 29, 30, 31, 32}. Gray mapper 940 can first generate the integer set Ψ([24: 24+9)) which is {20, 21, 23, 22, 18, 19, 17, 16, 48}. For every y∈Ψ([24: 24+9)), its binary representation (y₅,y₄,y₃,y₂,y₁,y₀) satisfying y₄=1 and y₃=0, such that other position indices are discrepant positions. Gray mapper 940 can then determine the set [symbol] (Ψ) of all discrepancy positions to be {0, 1, 2, 5}. Similarly, the set of indices with no discrepancy positions can be determined as {0, 1, 2, 3, 4, 5}\{0, 1, 2, 5}={3, 4}, whereas \hat{k}=|{3, 4}|=2. The 2 bits represented by indices {3, 4} are (1, 0), with the least significant bit as the rightmost bit. Sequence (1, 0) can be the output of amplitude deshaper 904.

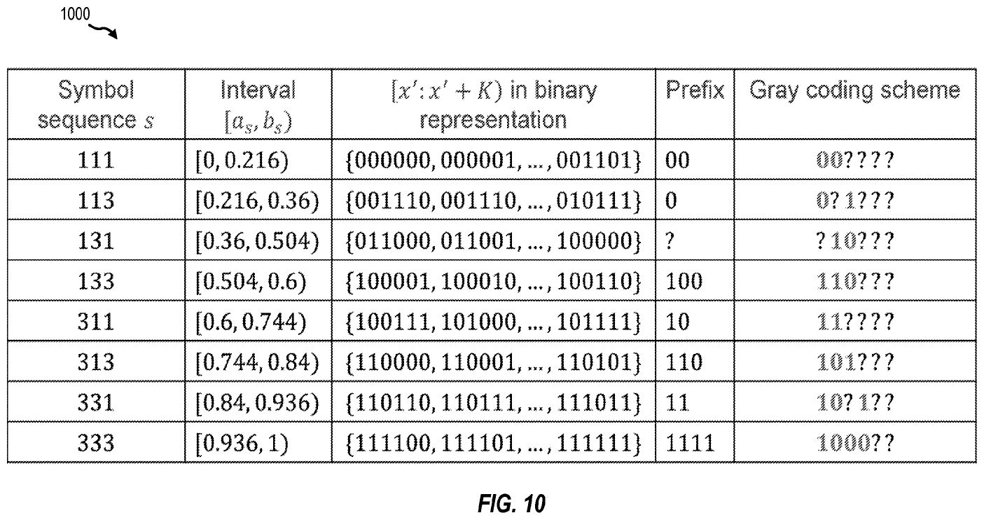

The table 1000 of FIG. 10 illustrates how Gray mapping may result in more common prefixes (non-discrepancy positions) than a conventional PAS approach. The parameters assumed for table 1000 are as follows: the symbol alphabet [symbol] ={1, 3} with probabilisty distribution p(1)=0.6 and p(0)=0.4, the symbol sequence length \hat{n}=3, entropy Hₚ=0.673 and information sequence length k=6. As noted above, these non-discrepancy positions are used to carry information bits for transmission, thus the Gray mapping may result in improved spectral efficiency.

As illustrated, for symbol sequence s=113, the number of common positions with no discrepancies may increase from 1 to 2. As illustrated, for symbol sequence s=131, the number of common positions with no discrepancies increases from 0 to 2.

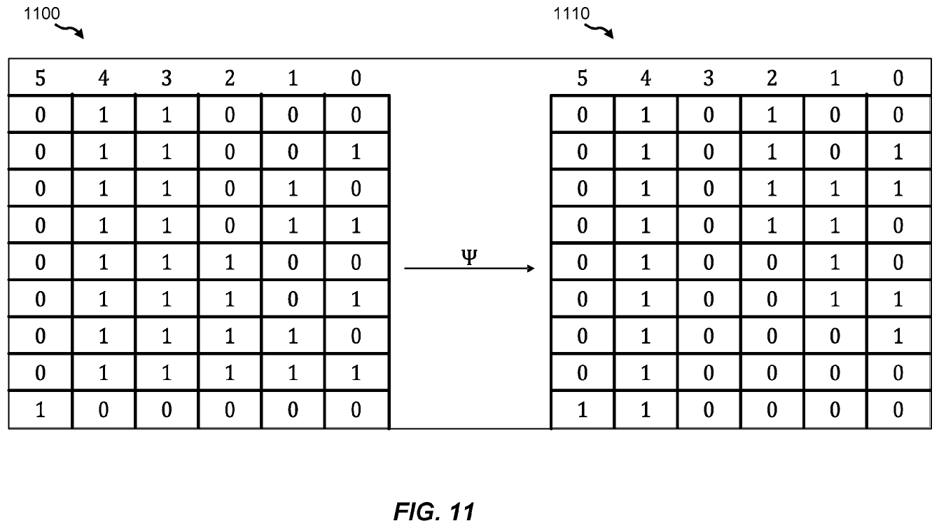

FIG. 11 illustrates how the Gray mapping function may result in the non-discrepancy positions {3, 4}. As illustrated, before Gray mapping, the set of binary representations 1100 lack any bit position with all the same values (e.g., no common prefix). After Gray mapping, however, the set of binary representations 1110 have two bit positions {3, 4} that have common values (0 and 1, respectively) such that positions {3, 4} are common positions with no discrepancies.

Table 1000 of FIG. 10 may be used in a variable-to-fixed distribution matching scheme to identify a number of information bits that have likely be received successfully at the receiver (by emulating receiver-side processing at the transmitter), in order to avoid transmitting extra bits that would likely be discarded at the receiver.

For example, as will be described in greater detail below, the table 1000 may allow the amplitude shaper at the transmitter-side and the amplitude deshaper at the receiver-side to know, based on the shaped symbol sequence, which bits had non-discrepancy positions (non-discrepancy bits, representing transmitted information bits) and which bits were discrepancy bits. This information allows the transmitter to know how to update the transmit (Tx) buffer (and what bits need to be retransmitted) and when the transmit buffer can be cleared (after all bits were transmitted as non-discrepancy bit positions). This information allows the receiver to know when an entire block of information bits has been successfully received, so that block may be delivered from the receive (Rx) buffer and those bits discarded from the Rx buffer.

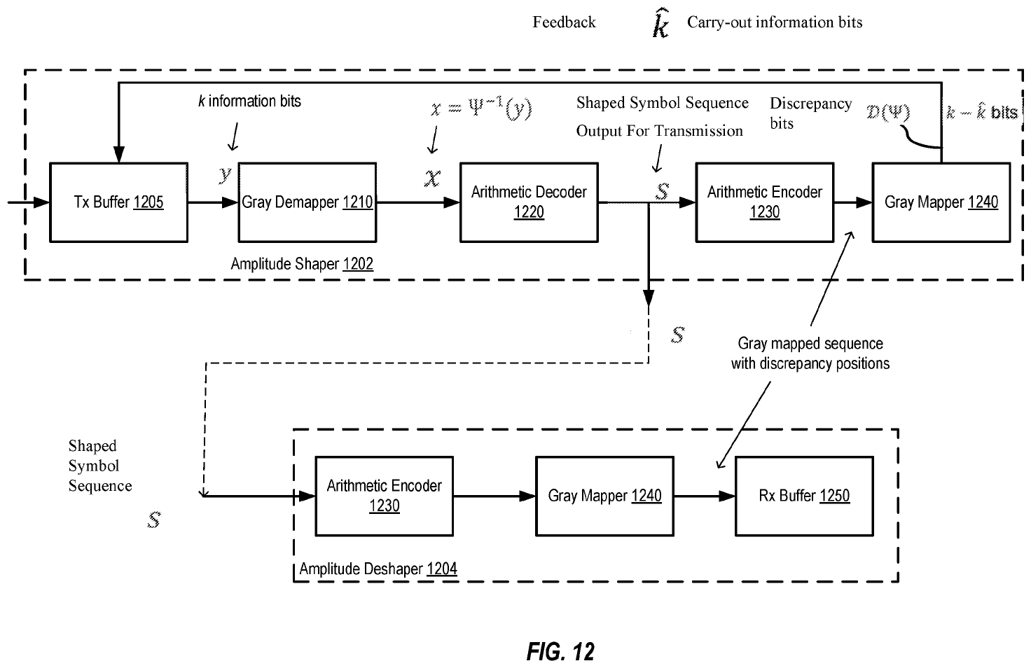

FIG. 12 illustrates an example amplitude shaper 1202 configured to perform variable-to-fixed distribution matching, enhanced with Gray mapping, to efficiently transmit information bits to a receiver with an amplitude deshaper 1204.

As illustrated, amplitude shaper 1202 can include a transmit (Tx) buffer 1205, Gray demapper 1210, arithmetic decoder 1220, arithmetic encoder 1230, and Gray mapper 1240.

Tx buffer 1205 can be a buffer that receives and stores blocks of information bits, each block of size k, for transmission. The Tx buffer stores the current block and all unprocessed blocks. Tx buffer 1205 can deliver a block of k information bits (e.g., Gray-coded information bits that may be referred to herein as “ordinary information bits” may be referred to as ordinary information bits) to the Gray demapper 1210. This block of k information bits correspond to an integer y. Gray demapper 1210 can perform an inverse Gray mapping of y to generate k information bits corresponding to an integer x, which can be used by arithmetic decoder 1220 to generate a sequence of shaped symbols for transmission. As described above with reference to table 1000 of FIG. 10, each sequence of shaped symbols may have a corresponding number of non-discrepancy bit positions (\hat{k}) that represent information bits conveyed by that particular shaped symbol sequence.

As illustrated, the first sequence S of shaped symbols can also be used by arithmetic encoder 1230 and Gray mapper 1240 to determine (e.g., per table 1000 of FIG. 10) a Gray mapped sequence with a set of discrepancy positions [symbol] (Ψ). This information may be used to effectively provide feedback information regarding the k-\hat{k} bits of the current block that need to be retransmitted.

The output from Gray mapper 1240 can be provided as feedback of the current block to Tx buffer 1205. Accordingly, Tx buffer 1205 can keep all k-\hat{k} bits in the current block corresponding to [symbol] (Ψ) and discard the \hat{k} bits of the current block corresponding to the set of indices without discrepancy positions. In other words, after the transmission, k-\hat{k} bits of the current block corresponding to [symbol] (Ψ) can be determined as not successfully delivered, and can be retained in the Tx buffer 1205 to use in a next transmission.

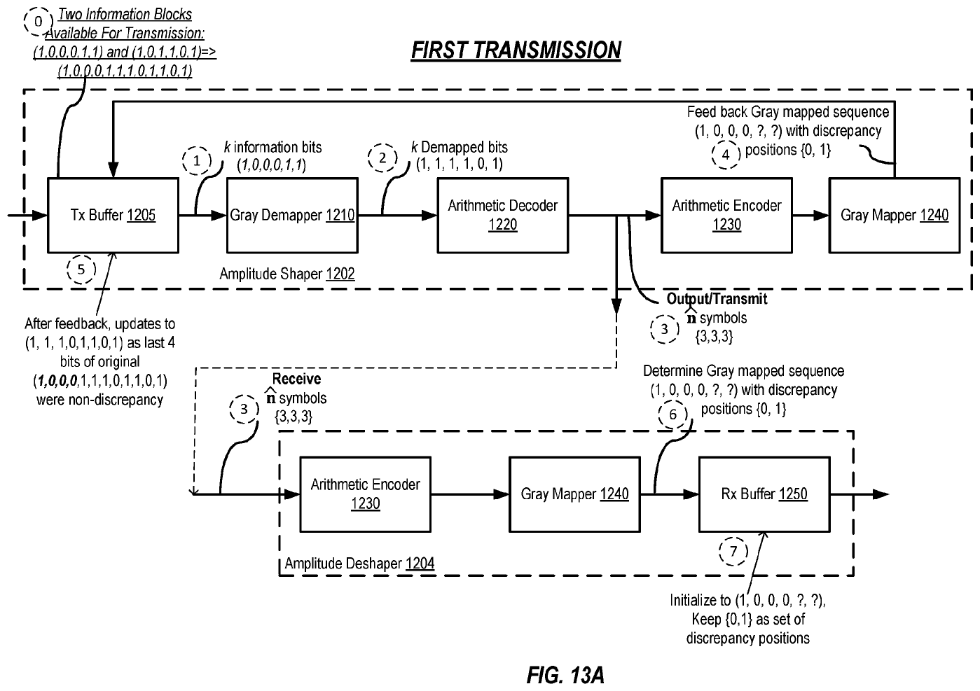

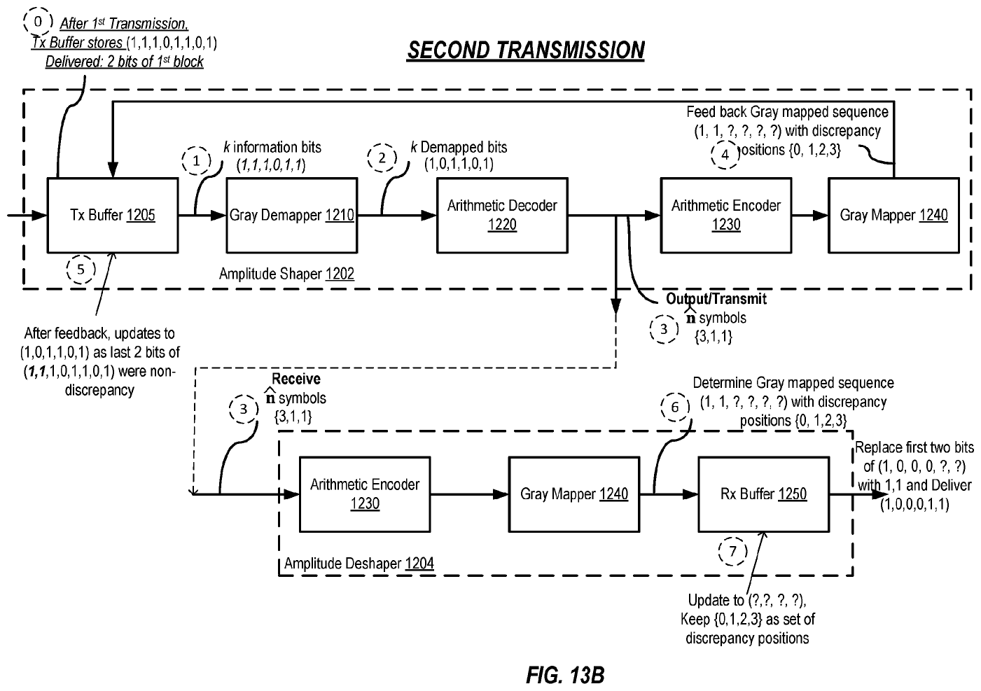

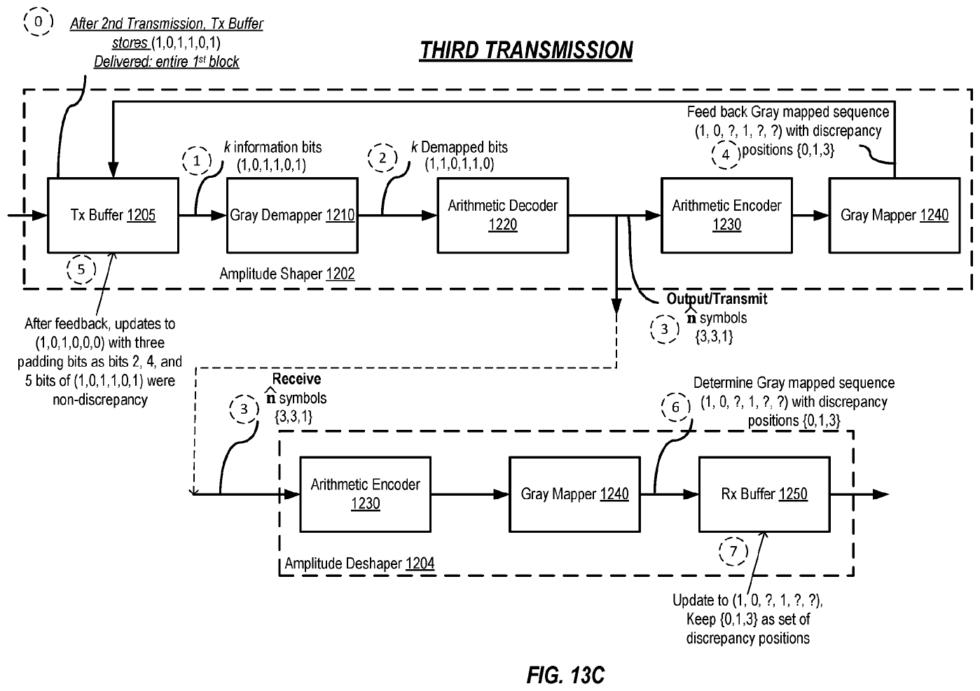

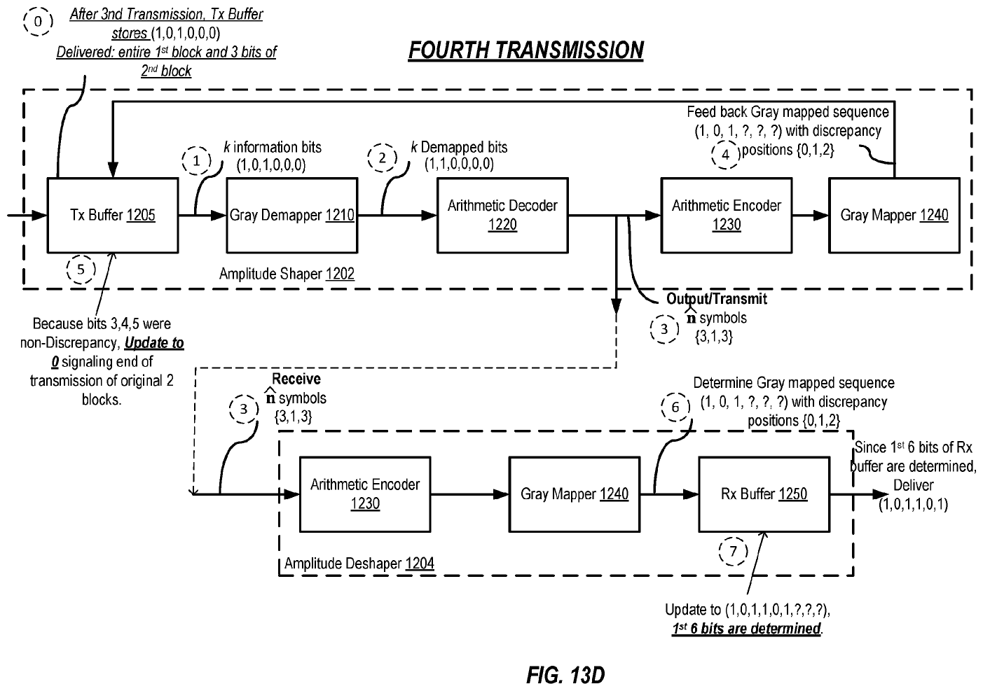

Without changing the ordering (e.g., such that the least significant bit corresponding to [symbol] (Ψ) remains the rightmost bit), the Tx buffer 1205 combines the k-\hat{k} bits of the current block corresponding to [symbol] (Ψ) from the feedback and the first k bits of the next block (e.g., appends the first \hat{k} bits of the next block to the k-\hat{k} bits of the current block) to form a new current block of k information bits. This new current block of k information bits can be the new input to the Gray demapper 1210. In some examples, as shown in FIG. 13C, zero padding may be used if there are not enough bits remaining in Tx buffer 1205 to form the new current block of k information bits.

As illustrated, amplitude deshaper 1204 can include arithmetic encoder 1230, Gray mapper 1240, and Rx buffer 1250. In some examples, arithmetic encoder 1230 is the same as or similar to arithmetic encoder 930, and Gray mapper 1240 the same as or similar to Gray mapper 940 as shown in FIG. 9B.

Amplitude deshaper 1204 can receive (over the wireless channel) the sequence of shaped symbols generated by arithmetic decoder 1220. The sequence of shaped symbols can be taken as input by arithmetic encoder 1230 and Gray mapper 1240 to determine (e.g., per table 1100 of FIG. 11) a Gray mapped sequence with a set of discrepancy positions [symbol] (Ψ), as discussed above.

Rx buffer 1250 can be initialized by reading through the first block of k values from the Gray mapper 1240. Rx buffer 1250 can record the indices of all undetermined values in the Rx buffer 1250 (e.g., corresponding to the discrepancy positions).

Upon receiving a new block B from the Gray mapper 1240, Rx buffer 1250 can first define an integer m to be the minimum of k and the number of undetermined values (e.g., same as the cardinality of the discrepancy positions) in Rx buffer 1250. For example, the new block B can be the same as the combined first subset of the first block of information bits and second block of information bits, as discussed above.

Rx buffer 1250 can then read the first m elements from the new block B, and replaces the first m undetermined values in Rx buffer 1250 with these m values from block B, without changing the order. For example, the least significant bit of the first m elements is assigned to the least significant bit of the undetermined values.

Rx buffer 1250 can then append the remaining k-m elements from block B at the end of Rx buffer 1250. Rx buffer 1250 can then determine, for the first k elements in Rx buffer 1250, if all of them have a determined value, and deliver such k elements and then discard them. Rx buffer 1250 can update the indices corresponding to undetermined values in Rx buffer 1250.

FIG. 13A, FIG. 13B, FIG. 13C, and FIG. 13D depict an example of iterative transmission processing with a transmitter and receiver incorporating Gray mapping into the amplitude shaper and deshaper, as shown in FIG. 12. The example assumes the same parameters as assumed for table 1000 of FIG. 10: the symbol alphabet [symbol] ={1, 3} with probabilisty distribution p(1)=0.6 and p(0)=0.4, the symbol sequence length \hat{n}=3, entropy Hₚ=0.673 and information sequence length k=6. The figures show the order of steps of processing performed at the amplitude shaper (e.g., steps 1-5) and amplitude deshaper (e.g., steps 6-7), though operations performed at the different entities may be performed simultaneously.

FIG. 13A illustrates the processing of amplitude shaper 1202 and amplitude deshaper 1204 to process an initial transmission. As illustrated, two blocks of information bits (1, 0, 0, 0, 1, 1) and (1, 0, 1, 1, 0, 1) are available for transmission. These may be concatenated and stored in the Tx buffer as (1, 0, 0, 0, 1, 1, 1, 0, 1, 1, 0, 1).

As illustrated in FIG. 13A, for the first transmission at the amplitude shaper, the first block of k information bits (1, 0, 0, 0, 1, 1) can be provided to the Gray demapper 1210, which performs an inverse Gray mapping to produce information bits (1, 1, 1, 1, 0, 1). Arithmetic decoder 1220 can take this block of bits as input and generate a first sequence of shaped symbols, (3, 3, 3) for transmission.

After the processing by the arithmetic encoder 1230, the Gray mapper 1240 determines (e.g., using table 1000 of FIG. 10) the set of discrepancy positions as {0, 1} and feedbacks this set to the Tx buffer. As shown in table 1000, this implies that (1, 0, 0, 0, ?, ?) is the “Gray-mapped” sequence. Based on this, the Tx buffer may be updated to (1, 1, 1, 0, 1, 1, 0, 1). This is because the first 4 elements in the original Tx buffer (1, 0, 0, 0, 1, 1, 1, 0, 1, 1, 0, 1) are transmitted without discrepancies and discarded, as they corresponded to (non-discrepancy position) information bits conveyed in the shaped symbols (3, 3, 3).

At the amplitude deshaper 1204, the symbol sequence (3, 3, 3) is received. After the processing by the arithmetic encoder, the Gray mapper determines the set of discrepancy positions as {0, 1}, as the “Gray-mapped” sequence is (1, 0, 0, 0, ?, ?). Based on this, the Rx buffer may be initialized to (1, 0, 0, 0, ?, ?) and the Rx buffer may keep {0, 1} as the set of discrepancy positions.

As illustrated in FIG. 13B, after the first transmission, the Tx Buffer stores (1, 1, 1, 0, 1, 1, 0, 1) and first 2 bits (e.g., (1, 1)) of the stored sequence of information bits are the bits with discrepancies in the first block of information bits (4 bits of the first block have been delivered).

For a second transmission at the amplitude shaper, the Gray demapper takes the first k bits from the Tx buffer containing (1, 1, 1, 0, 1, 1, 0, 1) and forms Ψ⁻¹(1, 1, 1, 0, 1, 1)=(1, 0, 1, 1, 0, 1). Arithmetic decoder 1220 can take this block of bits as input and generate a second sequence of shaped symbols, (3, 1, 1) for transmission.

After the processing by the arithmetic encoder 1230, the Gray mapper 1240 determines (e.g., using table 1000 of FIG. 10) the set of discrepancy positions as {0, 1, 2, 3} and feedbacks this set to the Tx buffer. As shown in table 1000, this implies that (1, 1, ?, ?, ?, ?) is the “Gray-mapped” sequence. Based on this, the Tx buffer may be updated to (1, 0, 1, 1, 0, 1). The first 2 elements in the original Tx buffer (1, 1, 1, 0, 1, 1, 0, 1) are transmitted without discrepancies and discarded (as the entire first original block has been transmitted).

At the amplitude deshaper 1204, the symbol sequence (3, 1, 1) is received. After the processing by the arithmetic encoder, the Gray mapper determines the set of discrepancy positions as {0, 1, 2, 3}, as the “Gray-mapped” sequence is (1, 1, ?, ?, ?, ?). Based on this, the Rx buffer may be updated to (?, ?, ?, ?) as the first 6 bits are determined and can be delivered (and discarded from the Rx buffer).

As illustrated in FIG. 13C, after the second transmission, the Tx Buffer stores (1, 0, 1, 1, 0, 1), the original second block of information bits, as all bits of the original first block of information bits have been delivered.

For a third transmission at the amplitude shaper, the Gray demapper takes the first k bits from the Tx buffer containing (1, 0, 1, 1, 0, 1) and forms Ψ⁻¹(1, 0, 1, 1, 0, 1)=(1, 1, 0, 1, 1, 0). Arithmetic decoder 1220 can take this block of bits as input and generate a third sequence of shaped symbols, (3, 3, 1) for transmission.

After the processing by the arithmetic encoder 1230, the Gray mapper 1240 determines (e.g., using table 1000 of FIG. 10) the set of discrepancy positions as {0, 1, 3} and feedbacks this set to the Tx buffer. As shown in table 1000, this implies that (1, 0, ?, 1, ?, ?) is the “Gray-mapped” sequence. Based on this, the Tx buffer may be updated to (1, 0, 1, 0, 0, 0) with 3 bits of zero padding. This is because the elements with index in {2, 4, 5} in the original Tx buffer (1, 0, 1, 1, 0, 1) are discarded.

At the amplitude deshaper 1204, the symbol sequence (3, 3, 1) is received. After the processing by the arithmetic encoder, the Gray mapper determines the set of discrepancy positions as {0, 1, 3}, as the “Gray-mapped” sequence is (1, 0, ?, 1, ?, ?). Based on this, the Rx buffer may be updated to (1, 0, ?, 1, ?, ?). This is because the amplitude deshaper replaces the 4 undetermined values in the original Rx buffer (?, ?, ?, ?) with the first 4 elements from the “Gray-mapped” sequence (1, 0, ?, 1, ?, ?) and appends to remaining 2 elements (?, ?) of the “Gray-mapped” sequence at the end of the Rx buffer, such that the Rx buffer becomes (1, 0, ?, 1, ?, ?).

As illustrated in FIG. 13D, after the third transmission, the Tx Buffer stores (1, 0, 1, 0, 0, 0) and 3 bits of the second block of information bits have been delivered.

For a fourth transmission at the amplitude shaper, the Gray demapper takes the first k bits from the Tx buffer containing (1, 0, 1, 0, 0, 0) and forms Ψ⁻¹(1, 0, 1, 0, 0, 0)=(1, 1, 0, 0, 0, 0). Arithmetic decoder 1220 can take this block of bits as input and generate a fourth sequence of shaped symbols, (3, 1, 3) for transmission.

After the processing by the arithmetic encoder 1230, the Gray mapper 1240 determines (e.g., using table 1000 of FIG. 10) the set of discrepancy positions as {0, 1, 2} and feedbacks this set to the Tx buffer. As shown in table 1000, this implies that (1, 0, 1, ?, ?, ?) is the “Gray-mapped” sequence. Based on this, the Tx buffer may be updated to 0 (cleared/reset), as both of the original blocks have been transmitted.

At the amplitude deshaper 1204, the symbol sequence (3, 1, 3) is received. After the processing by the arithmetic encoder, the Gray mapper determines the set of discrepancy positions as {0, 1, 2}, as the “Gray-mapped” sequence is (1, 0, 1, ?, ?, ?). Based on this, the amplitude deshaper may replace the 3 undetermined values in the original Rx buffer (1, 0, ?, 1, ?, ?) with the first 3 elements from the “Gray-mapped” sequence (1, 0, 1, ?, ?, ?). The amplitude deshaper may also append the remaining 3 elements (?, ?, ?) of the “Gray-mapped” sequence at the end of the Rx buffer, such that the values stored in the Rx buffer becomes.

Since the first 6 elements of the Rx buffer are all determined, they are delivered and are then discarded. Since this was the second block of original information bits from the Tx buffer, this corresponds to the end of information transmission.

### Example Operations of a Transmitter

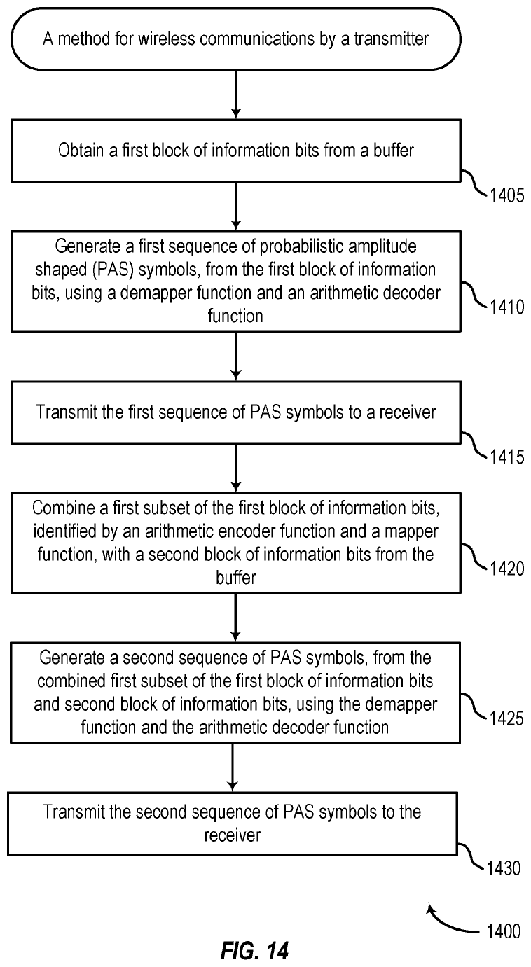

FIG. 14 shows an example of a method 1400 for wireless communications by a transmitter. In some aspects, the transmitter is a UE, such as a UE 104 of FIGS. 1 and 3. In some aspects, the transmitter is a network entity, such as a BS 102 of FIGS. 1 and 3, or a disaggregated base station as discussed with respect to FIG. 2.

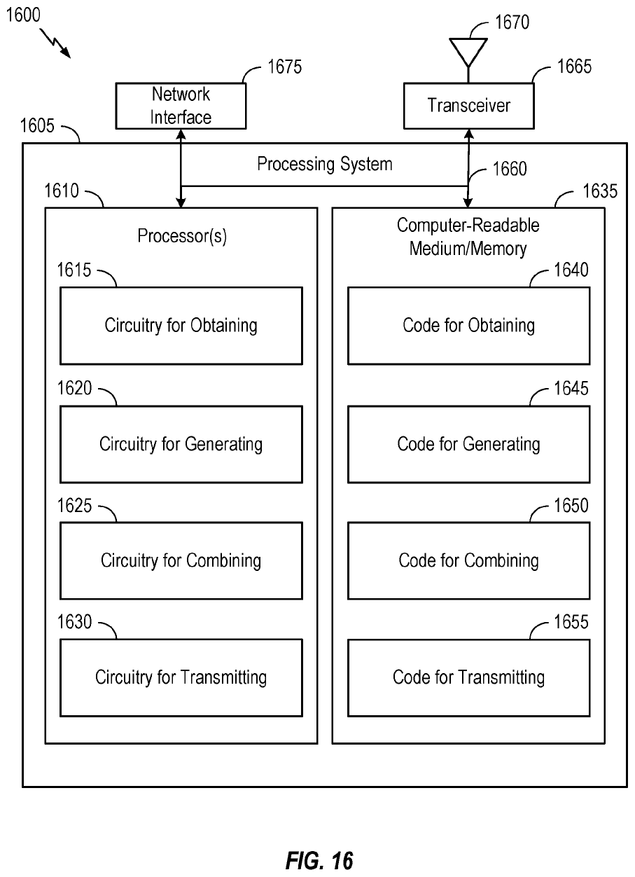

Method 1400 begins at step 1405 with obtaining a first block of information bits from a buffer. In some cases, the operations of this step refer to, or may be performed by, circuitry for obtaining and/or code for obtaining as described with reference to FIG. 16.

Method 1400 then proceeds to step 1410 with generating a first sequence of probabilistic amplitude shaped (PAS) symbols, from the first block of information bits, using a demapper function and an arithmetic decoder function. In some cases, the operations of this step refer to, or may be performed by, circuitry for generating and/or code for generating as described with reference to FIG. 16.

Method 1400 then proceeds to step 1415 with transmitting the first sequence of PAS symbols to a receiver. In some cases, the operations of this step refer to, or may be performed by, circuitry for transmitting and/or code for transmitting as described with reference to FIG. 16.

Method 1400 then proceeds to step 1420 with combining a first subset of the first block of information bits, identified by an arithmetic encoder function and a mapper function, with a second block of information bits from the buffer. In some cases, the operations of this step refer to, or may be performed by, circuitry for combining and/or code for combining as described with reference to FIG. 16.

Method 1400 then proceeds to step 1425 with generating a second sequence of PAS symbols, from the combined first subset of the first block of information bits and second block of information bits, using the demapper function and the arithmetic decoder function. In some cases, the operations of this step refer to, or may be performed by, circuitry for transmitting and/or code for transmitting as described with reference to FIG. 16.

Method 1400 then proceeds to step 1430 with transmitting the second sequence of PAS symbols to the receiver. In some cases, the operations of this step refer to, or may be performed by, circuitry for transmitting and/or code for transmitting as described with reference to FIG. 16.

In one aspect, method 1400, or any aspect related to it, may be performed by an apparatus, such as communications device 1600 of FIG. 16, which includes various components operable, configured, or adapted to perform the method 1400. Communications device 1600 is described below in further detail.

Note that FIG. 14 is just one example of a method, and other methods including fewer, additional, or alternative steps are possible consistent with this disclosure.

### Example Operations of a Receiver

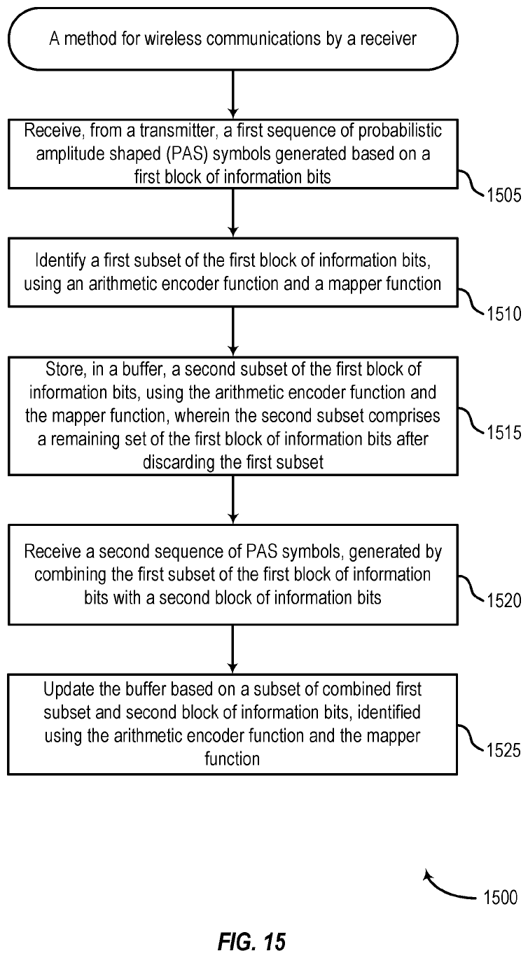

FIG. 15 shows an example of a method 1500 for wireless communications by a receiver. In some aspects, the receiver is a UE, such as a UE 104 of FIGS. 1 and 3. In some aspects, the receiver is a network entity, such as a BS 102 of FIGS. 1 and 3, or a disaggregated base station as discussed with respect to FIG. 2.

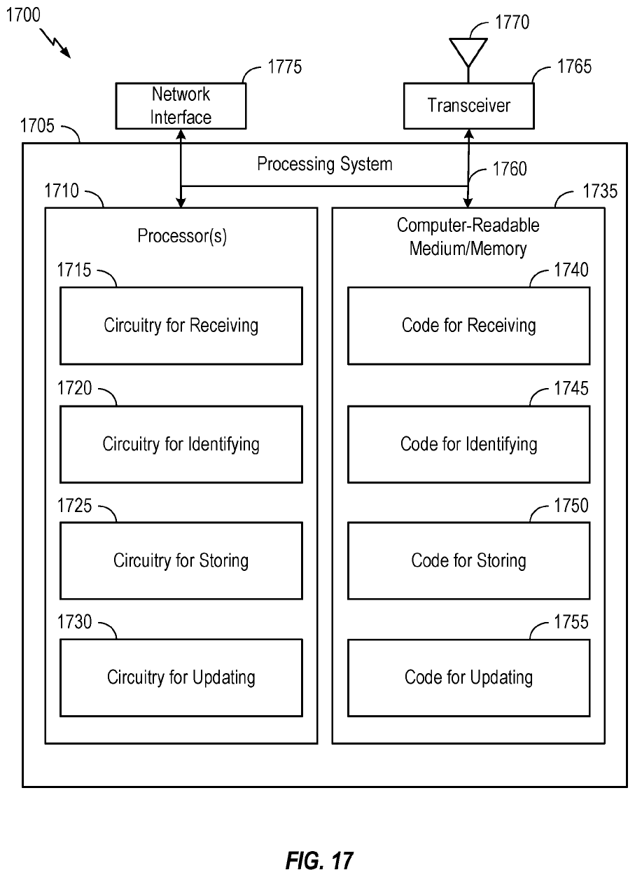

Method 1500 begins at step 1505 with receiving, from a transmitter, a first sequence of probabilistic amplitude shaped (PAS) symbols generated based on a first block of information bits. In some cases, the operations of this step refer to, or may be performed by, circuitry for receiving and/or code for receiving as described with reference to FIG. 17.

Method 1500 then proceeds to step 1510 with identifying a first subset of the first block of information bits, using an arithmetic encoder function and a mapper function. In some cases, the operations of this step refer to, or may be performed by, circuitry for identifying and/or code for identifying as described with reference to FIG. 17.

Method 1500 then proceeds to step 1515 with storing, in a buffer, a second subset of the first block of information bits, using the arithmetic encoder function and the mapper function, wherein the second subset comprises a remaining set of the first block of information bits after discarding the first subset. In some cases, the operations of this step refer to, or may be performed by, circuitry for storing and/or code for storing as described with reference to FIG. 17.

Method 1500 begins at step 1520 with receiving a second sequence of PAS symbols, generated by combining the first subset of the first block of information bits with a second block of information bits. In some cases, the operations of this step refer to, or may be performed by, circuitry for receiving and/or code for receiving as described with reference to FIG. 17.

Method 1500 begins at step 1525 with updating the buffer based on a subset of combined first subset and second block of information bits, identified using the arithmetic encoder function and the mapper function. In some cases, the operations of this step refer to, or may be performed by, circuitry for updating and/or code for updating as described with reference to FIG. 17.

In one aspect, method 1500, or any aspect related to it, may be performed by an apparatus, such as communications device 1700 of FIG. 17, which includes various components operable, configured, or adapted to perform the method 1500. Communications device 1700 is described below in further detail.

Note that FIG. 15 is just one example of a method, and other methods including fewer, additional, or alternative steps are possible consistent with this disclosure.

### Example Transmitter Device

FIG. 16 depicts aspects of an example communications device 1600. In some aspects, communications device 1600 is a user equipment, such as a UE 104 described above with respect to FIGS. 1 and 3. In some aspects, communications device 1600 is a network entity, such as a BS 102 of FIGS. 1 and 3, or a disaggregated base station as discussed with respect to FIG. 2.

The communications device 1600 includes a processing system 1605 coupled to the transceiver 1665 (e.g., a transmitter and/or a receiver). In some aspects (e.g., when communications device 1600 is a network entity), processing system 1605 may be coupled to a network interface 1675 that is configured to obtain and send signals for the communications device 1600 via communication link(s), such as a backhaul link, midhaul link, and/or fronthaul link as described herein, such as with respect to FIG. 2. The transceiver 1665 is configured to transmit and receive signals for the communications device 1600 via the antenna 1670, such as the various signals as described herein. The processing system 1605 may be configured to perform processing functions for the communications device 1600, including processing signals received and/or to be transmitted by the communications device 1600.

The processing system 1605 includes one or more processors 1610. In various aspects, the one or more processors 1610 may be representative of one or more of receive processor 358, transmit processor 364, TX MIMO processor 366, and/or controller/processor 380, as described with respect to FIG. 3. In various aspects, one or more processors 1610 may be representative of one or more of receive processor 338, transmit processor 320, TX MIMO processor 330, and/or controller/processor 340, as described with respect to FIG. 3. The one or more processors 1610 are coupled to a computer-readable medium/memory 1635 via a bus 1660. In certain aspects, the computer-readable medium/memory 1635 is configured to store instructions (e.g., computer-executable code) that when executed by the one or more processors 1610, cause the one or more processors 1610 to perform the method 1400 described with respect to FIG. 14, or any aspect related to it. Note that reference to a processor performing a function of communications device 1600 may include one or more processors 1610 performing that function of communications device 1600.

In the depicted example, computer-readable medium/memory 1635 stores code (e.g., executable instructions), such as code for obtaining 1640, code for generating 1645, code for combining 1650, and code for transmitting 1655. Processing of the code for obtaining 1640, code for generating 1645, code for combining 1650, and code for transmitting 1655 may cause the communications device 1600 to perform the method 1400 described with respect to FIG. 14, or any aspect related to it.

The one or more processors 1610 include circuitry configured to implement (e.g., execute) the code stored in the computer-readable medium/memory 1635, including circuitry such as circuitry for obtaining 1615, circuitry for generating 1620, circuitry for combining 1625, and circuitry for transmitting 1630. Processing with circuitry for obtaining 1615, circuitry for generating 1620, circuitry for combining 1625, and circuitry for transmitting 1630 may cause the communications device 1600 to perform the method 1400 described with respect to FIG. 14, or any aspect related to it.

Various components of the communications device 1600 may provide means for performing the method 1400 described with respect to FIG. 14, or any aspect related to it. For example, means for transmitting, sending or outputting for transmission may include transceivers 354 and/or antenna(s) 352 of the UE 104 illustrated in FIG. 3, transceivers 332 and/or antenna(s) 334 of the BS 102 illustrated in FIG. 3, and/or the transceiver 1665 and the antenna 1670 of the communications device 1600 in FIG. 16. Means for receiving or obtaining may include transceivers 354 and/or antenna(s) 352 of the UE 104 illustrated in FIG. 3, transceivers 332 and/or antenna(s) 334 of the BS 102 illustrated in FIG. 3, and/or the transceiver 1665 and the antenna 1670 of the communications device 1600 in FIG. 16.

### Example Receiver Device

FIG. 17 depicts aspects of an example communications device 1700. In some aspects, communications device 1700 is a user equipment, such as a UE 104 described above with respect to FIGS. 1 and 3. In some aspects, communications device 1700 is a network entity, such as a BS 102 of FIGS. 1 and 3, or a disaggregated base station as discussed with respect to FIG. 2.

The communications device 1700 includes a processing system 1705 coupled to the transceiver 1755 (e.g., a transmitter and/or a receiver). In some aspects (e.g., when communications device 1700 is a network entity), processing system 1705 may be coupled to a network interface 1765 that is configured to obtain and send signals for the communications device 1700 via communication link(s), such as a backhaul link, midhaul link, and/or fronthaul link as described herein, such as with respect to FIG. 2. The transceiver 1755 is configured to transmit and receive signals for the communications device 1700 via the antenna 1760, such as the various signals as described herein. The processing system 1705 may be configured to perform processing functions for the communications device 1700, including processing signals received and/or to be transmitted by the communications device 1700.

The processing system 1705 includes one or more processors 1710. In various aspects, the one or more processors 1710 may be representative of one or more of receive processor 358, transmit processor 364, TX MIMO processor 366, and/or controller/processor 380, as described with respect to FIG. 3. In various aspects, one or more processors 1710 may be representative of one or more of receive processor 338, transmit processor 320, TX MIMO processor 330, and/or controller/processor 340, as described with respect to FIG. 3. The one or more processors 1710 are coupled to a computer-readable medium/memory 1730 via a bus 1750. In certain aspects, the computer-readable medium/memory 1730 is configured to store instructions (e.g., computer-executable code) that when executed by the one or more processors 1710, cause the one or more processors 1710 to perform the method 1500 described with respect to FIG. 15, or any aspect related to it. Note that reference to a processor performing a function of communications device 1700 may include one or more processors 1710 performing that function of communications device 1700.

In the depicted example, computer-readable medium/memory 1735 stores code (e.g., executable instructions), such as code for receiving 1740, code for identifying 1745, code for storing 1750, and code for updating 1755. Processing of the code for receiving 1740, code for identifying 1745, and code for storing 1750, and code for updating 1755 may cause the communications device 1700 to perform the method 1500 described with respect to FIG. 15, or any aspect related to it.

The one or more processors 1710 include circuitry configured to implement (e.g., execute) the code stored in the computer-readable medium/memory 1730, including circuitry such as circuitry for receiving 1715, circuitry for identifying 1720, circuitry for storing 1725, and circuitry for updating 1730. Processing with circuitry for receiving 1715, circuitry for identifying 1720, circuitry for storing 1725, and circuitry for updating 1730 may cause the communications device 1700 to perform the method 1500 described with respect to FIG. 15, or any aspect related to it.

Various components of the communications device 1700 may provide means for performing the method 1500 described with respect to FIG. 15, or any aspect related to it. For example, means for transmitting, sending or outputting for transmission may include transceivers 354 and/or antenna(s) 352 of the UE 104 illustrated in FIG. 3, transceivers 332 and/or antenna(s) 334 of the BS 102 illustrated in FIG. 3, and/or the transceiver 1755 and the antenna 1760 of the communications device 1700 in FIG. 17. Means for receiving or obtaining may include transceivers 354 and/or antenna(s) 352 of the UE 104 illustrated in FIG. 3, transceivers 332 and/or antenna(s) 334 of the BS 102 illustrated in FIG. 3, and/or the transceiver 1755 and the antenna 1760 of the communications device 1700 in FIG. 17.

### EXAMPLE CLAUSES

Implementation examples are described in the following numbered clauses:

Clause 1: A method of wireless communication at a transmitter, comprising: obtaining a first block of information bits from a buffer; generating a first sequence of probabilistic amplitude shaped (PAS) symbols, from the first block of information bits, using a demapper function and an arithmetic decoder function; transmitting the first sequence of PAS symbols to a receiver; combining a first subset of the first block of information bits, identified by an arithmetic encoder function and a mapper function, with a second block of information bits from the buffer; generating a second sequence of PAS symbols, from the combined first subset of the first block of information bits and second block of information bits, using the demapper function and the arithmetic decoder function; and transmitting the second sequence of PAS symbols to the receiver.

Clause 2: The method of Clause 1, wherein: the demapper function comprises a Gray demapper function that maps a set of ordinary information bits to a set of Gray demapped bits; and the mapper function comprises a Gray mapper function that maps a set of Gray demapped bits to a set of Gray mapped bits.

Clause 3: The method of Clause 2, wherein the first block of information bits represents a first integer and generating the first sequence of PAS symbols comprises: forming, with the Gray demapper function, a second integer from the first integer; and forming the first sequence of PAS symbols, with the arithmetic decoder, from the second integer.

Clause 4: The method of Clause 3, further comprising identifying the first subset of bits of the first block of information bits by: generating a set of integers from the first sequence of PAS symbols, using the arithmetic encoder; and identifying a second subset of the first block of information bits that correspond to a number of bit positions that have common values of all binary representations of the integers in the set of integers.

Clause 5: The method of Clause 4, wherein the first subset of bits correspond to discrepancy bit positions that lack common values of all binary representations of the integers.

Clause 6: The method of any one of Clauses 1-5, further comprising: combining a subset of the second block of information bits, identified by the arithmetic encoder function and the mapper function, with a third block of information bits; generating a third sequence of PAS symbols, from a first block of information bits, using the demapper function and the arithmetic decoder function; and transmitting the third sequence of PAS symbols to the receiver.

Clause 7: A method of wireless communication at a receiver, comprising: receiving, from a transmitter, a first sequence of probabilistic amplitude shaped (PAS) symbols generated based on a first block of information bits; identifying a first subset of the first block of information bits, using an arithmetic encoder function and a mapper function; storing, in a buffer, a second subset of the first block of information bits, using the arithmetic encoder function and the mapper function, wherein the second subset comprises a remaining set of the first block of information bits after discarding the first subset; receiving a second sequence of PAS symbols, generated by combining the first subset of the first block of information bits with a second block of information bits; and updating the buffer based on a subset of combined first subset and second block of information bits, identified using the arithmetic encoder function and the mapper function.

Clause 8: The method of Clause 7, further comprising: determining, using the arithmetic encoder function and the mapper function, that a number of bits in the buffer are successfully received; delivering that number of bits to another function of the receiver; and discarding that number of bits from the buffer.

Clause 9: The method of any one of Clauses 7-8, wherein: the mapper function comprises a Gray mapper function.

Clause 10: The method of Clause 9, wherein: the first block of information bits represents a first integer; and the first sequence of PAS symbols is generated based on a second integer formed from the first integer using a Gray demapper function.

Clause 11: The method of Clause 10, further comprising identifying the first subset of bits of the first block of information bits by: generating a set of integers from the first sequence of PAS symbols, using the arithmetic encoder; and identifying a number of bit positions that have common values of all binary representations of the integers in the set of integers.

Clause 12: The method of Clause 11, wherein the first subset of bits correspond to discrepancy positions that lack common values of all binary representations of the integers.

Clause 13: An apparatus, comprising: a memory comprising executable instructions; and a processor configured to execute the executable instructions and cause the apparatus to perform a method in accordance with any one of Clauses 1-12.

Clause 14: An apparatus, comprising means for performing a method in accordance with any one of Clauses 1-12.

Clause 15: A non-transitory computer-readable medium comprising executable instructions that, when executed by a processor of an apparatus, cause the apparatus to perform a method in accordance with any one of Clauses 1-12.

Clause 16: A computer program product embodied on a computer-readable storage medium comprising code for performing a method in accordance with any one of Clauses 1-12.

### ADDITIONAL CONSIDERATIONS

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), or any other such configuration.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for”. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

1. A method of wireless communication at a transmitter, comprising:
obtaining a first block of information bits from a buffer;
generating a first sequence of probabilistic amplitude shaped (PAS) symbols, from the first block of information bits, using a demapper function and an arithmetic decoder function;
transmitting the first sequence of PAS symbols to a receiver;
combining a first subset of the first block of information bits, identified by an arithmetic encoder function and a mapper function, with a second block of information bits from the buffer;
generating a second sequence of PAS symbols, from the combined first subset of the first block of information bits and second block of information bits, using the demapper function and the arithmetic decoder function; and
transmitting the second sequence of PAS symbols to the receiver.

2. The method of 1, wherein:
the demapper function comprises a Gray demapper function that maps a set of ordinary information bits to a set of Gray demapped bits; and
the mapper function comprises a Gray mapper function that maps a set of Gray demapped bits to a set of Gray mapped bits.

3. The method of claim 2, wherein the first block of information bits represents a first integer and generating the first sequence of PAS symbols comprises:
forming, with the Gray demapper function, a second integer from the first integer; and
forming the first sequence of PAS symbols, with the arithmetic decoder function, from the second integer.

4. The method of claim 3, further comprising identifying the first subset of bits of the first block of information bits by:
generating a set of integers from the first sequence of PAS symbols, using the arithmetic encoder function; and
identifying a second subset of the first block of information bits that correspond to a number of bit positions that have common values of all binary representations of the integers in the set of integers.

5. The method of claim 4, wherein the first subset of bits correspond to discrepancy bit positions that lack common values of all binary representations of the integers.

6. The method of claim 1, further comprising:
combining a subset of the second block of information bits, identified by the arithmetic encoder function and the mapper function, with a third block of information bits;
generating a third sequence of PAS symbols, from a first block of information bits, using the demapper function and the arithmetic decoder function; and
transmitting the third sequence of PAS symbols to the receiver.

7. A method of wireless communication at a receiver, comprising:
receiving, from a transmitter, a first sequence of probabilistic amplitude shaped (PAS) symbols generated based on a first block of information bits;
identifying a first subset of the first block of information bits, using an arithmetic encoder function and a mapper function;
storing, in a buffer, a second subset of the first block of information bits, using the arithmetic encoder function and the mapper function, wherein the second subset comprises a remaining set of the first block of information bits after discarding the first subset;
receiving a second sequence of PAS symbols, generated by combining the first subset of the first block of information bits with a second block of information bits; and
updating the buffer based on a subset of combined first subset and second block of information bits, identified using the arithmetic encoder function and the mapper function.

8. The method of claim 7, further comprising:
determining, using the arithmetic encoder function and the mapper function, that a number of bits in the buffer are successfully received;
delivering that number of bits to another function of the receiver; and
discarding that number of bits from the buffer.

9. The method of claim 7, wherein:
the mapper function comprises a Gray mapper function.

10. The method of claim 9, wherein:
the first block of information bits represents a first integer; and
the first sequence of PAS symbols is generated based on a second integer formed from the first integer using a Gray demapper function.

11. The method of claim 10, further comprising identifying the first subset of bits of the first block of information bits by:
generating a set of integers from the first sequence of PAS symbols, using the arithmetic encoder function; and
identifying a number of bit positions that have common values of all binary representations of the integers in the set of integers.

12. The method of claim 11, wherein the first subset of bits correspond to discrepancy positions that lack common values of all binary representations of the integers.

13. An apparatus for wireless communication by a transmitter, comprising:
a memory; and
at least one processor coupled with the memory, wherein the memory includes instructions executable by the at least one processor to cause the transmitter to:
obtain a first block of information bits from a buffer;
generate a first sequence of probabilistic amplitude shaped (PAS) symbols, from the first block of information bits, using a demapper function and an arithmetic decoder function;
transmit the first sequence of PAS symbols to a receiver;
combine a first subset of the first block of information bits, identified by an arithmetic encoder function and a mapper function, with a second block of information bits from the buffer;
generate a second sequence of PAS symbols, from the combined first subset of the first block of information bits and second block of information bits, using the demapper function and the arithmetic decoder function; and
transmit the second sequence of PAS symbols to the receiver.

14. The apparatus of claim 13, wherein:
the demapper function comprises a Gray demapper function that maps a set of ordinary information bits to a set of Gray demapped bits; and
the mapper function comprises a Gray mapper function that maps a set of Gray demapped bits to a set of Gray mapped bits.

15. The apparatus of claim 14, wherein the first block of information bits represents a first integer and generating the first sequence of PAS symbols comprises:
forming, with the Gray demapper function, a second integer from the first integer; and
forming the first sequence of PAS symbols, with the arithmetic decoder function, from the second integer.

16. The apparatus of claim 15, wherein the memory further includes instructions executable by the at least one processor to cause the transmitter to identify the first subset of bits of the first block of information bits by:
generating a set of integers from the first sequence of PAS symbols, using the arithmetic encoder function; and
identifying a second subset of the first block of information bits that correspond to a number of bit positions that have common values of all binary representations of the integers in the set of integers.

17. The apparatus of claim 16, wherein the first subset of bits correspond to discrepancy bit positions that lack common values of all binary representations of the integers.

18. The apparatus of claim 13, wherein the memory includes instructions executable by the at least one processor to cause the transmitter to:
combine a subset of the second block of information bits, identified by the arithmetic encoder function and the mapper function, with a third block of information bits;
generate a third sequence of PAS symbols, from a first block of information bits, using the demapper function and the arithmetic decoder function; and
transmit the third sequence of PAS symbols to the receiver.

19. An apparatus for wireless communication by a receiver, comprising:
a memory; and
at least one processor coupled with the memory, wherein the memory includes instructions executable by the at least one processor to cause the receiver to:
receive, from a transmitter, a first sequence of probabilistic amplitude shaped (PAS) symbols generated based on a first block of information bits;
identify a first subset of the first block of information bits, using an arithmetic encoder function and a mapper function;
store, in a buffer, a second subset of the first block of information bits, using the arithmetic encoder function and the mapper function, wherein the second subset comprises a remaining set of the first block of information bits after discarding the first subset;
receive a second sequence of PAS symbols, generated by combining the first subset of the first block of information bits with a second block of information bits; and
update the buffer based on a subset of combined first subset and second block of information bits, identified using the arithmetic encoder function and the mapper function.

20. The apparatus of claim 19, wherein the memory further includes instructions executable by the at least one processor to cause the receiver to:
determine, using the arithmetic encoder function and the mapper function, that a number of bits in the buffer are successfully received;
deliver that number of bits to another function of the receiver; and
discard that number of bits from the buffer.

21. The apparatus of claim 19, wherein:
the mapper function comprises a Gray mapper function.

22. The apparatus of claim 21, wherein:
the first block of information bits represents a first integer; and
the first sequence of PAS symbols is generated based on a second integer formed from the first integer using a Gray demapper function.

23. The apparatus of claim 22, wherein the memory includes instructions executable by the at least one processor to cause the receiver to identify the first subset of bits of the first block of information bits by:
generating a set of integers from the first sequence of PAS symbols, using the arithmetic encoder function; and
identifying a number of bit positions that have common values of all binary representations of the integers in the set of integers.

24. The apparatus of claim 23, wherein the first subset of bits correspond to discrepancy positions that lack common values of all binary representations of the integers.
